(19) United States
(12) Patent Application Publication
(10) Pub. No.: US 2011/0294244 A1
(43) Pub. Date: Dec. 1, 2011

(54) METHOD FOR MANUFACTURING DISPLAY DEVICE

(75) Inventors: Takashi HATTORI, Musashimurayama (JP); Takahide Kuranaga, Mobara (JP); Naoya Okada, Chiba (JP); Mutsuko Hatano, Kokubunji (JP)

(73) Assignees: Panasonic Liquid Crystal Display Co., Ltd.; Hitachi Displays, Ltd.

(21) Appl. No.: 13/114,074

(22) Filed: May 24, 2011

(30) Foreign Application Priority Data
May 26, 2010 (JP) 2010-120824

(51) Int. Cl. H01L 33/08

(52) U.S. Cl. 438/34; 257/E33.005

(57) ABSTRACT

Provided is a method of manufacturing a display device, including: forming a polymer layer which includes an organic material on a principal surface side of a support substrate; forming one of a semiconductor circuit and a display circuit on the polymer layer; irradiating the polymer layer from the support substrate side with light having a wavelength that is absorbed in the polymer layer, to thereby separate the polymer layer from the support substrate; one of thinning and removing the polymer layer; and adhering a first substrate to one of a surface of the polymer layer and a face where the polymer layer has been provided.

### CROSS-REFERENCE TO RELATED APPLICATION

The present application claims priority from Japanese application JP 2010-120824 filed on May 26, 2010, the content of which is hereby incorporated by reference into this application.

### BACKGROUND OF THE INVENTION

1. Field of the Invention

The present invention relates to a method of manufacturing a display device.

2. Description of the Related Art

In order to achieve a light weight flat panel display typified by a liquid crystal display device, there have been studied to make a substrate thinner than conventional substrates. The liquid crystal display device manufactured at present usually uses a glass substrate having a thickness of about 0.5 mm to 1.1 mm. The glass substrate thinner than the thickness easily breaks during a manufacturing step or in use of the liquid crystal display device. As one of solutions to this, there are being developed liquid crystal display devices that use a plastic substrate instead of the glass substrate.

However, the plastic substrate usually has a heat resistance of around 200° C., which is lower than the heat resistance of the glass substrate at around 600° C. At present, an amorphous silicon (a-Si) thin film transistor and a low temperature polysilicon (LIPS) thin film transistor are formed at around 300° C. and 500° C., respectively, which are far higher than the heat resistance of the plastic substrate. As a solution, therefore, lowering of the formation temperature of the thin film transistor is being studied.

In addition, the plastic substrates are generally soft and flexible unlike the glass substrates. As such, it is generally difficult to manufacture the plastic substrate in an existing manufacturing line that is designed for the glass substrate without some adjustments. As a countermeasure, switching the manufacturing line for the glass substrate to a roll-to-roll system is being considered.

On the other hand, transferring a thin film transistor formed on the glass substrate to a plastic substrate is being studied as a method that allows the continued use of the existing manufacturing line without any adjustments. Methods which make easier the transfer of the thin film transistor formed on the glass substrate to the plastic substrate include one of thinning the glass substrate by etching, and one of forming in advance a separating layer on the glass substrate and then separating the separating layer after formation of the thin film transistor. In either method, a glass portion where the thin film transistor is formed is made thinner and then transplanted onto the plastic substrate. Another transfer method involves adhering, or otherwise attaching, the plastic substrate onto the glass substrate, forming a thin film transistor on the attached substrate, and then separating the plastic substrate.

Related film transferring methods to the present invention are disclosed in Japanese Patent Application Laid-open Nos. 2000-243943, 2000-284303, 2002-33464, 2002-31818, 2006-287068, 2009-265396, 2009-188317, 2009-260387, 2009-031405, and 2008-292608.

The method, which involves forming the thin film transistor temporarily on the glass substrate serving as a support substrate, and then thinning the glass substrate, has an advantage in that the existing manufacturing line and the current process temperature which is set for glass substrates, can be used. However, when the glass substrate serving as the support substrate is thinned by etching, there is a fear of wasting almost all the glass substrate, resulting in an increase in cost.

The method which involves adhering, or otherwise attaching, the plastic substrate to the glass substrate, forming the thin film transistor on the plastic substrate, and then separating the glass substrate from the plastic substrate needs to lower the process temperature because the plastic substrates are lower in heat resistance than the glass substrates. It may consequently be difficult to obtain a device of excellent characteristics with this method.

Besides, there is known a method in which the separating layer is formed on the glass substrate, and the thin film transistor, etc. are formed on the separating layer. In this case, when the separating layer is formed from an inorganic material such as an amorphous silicon layer in consideration of light transmission performance, there is required an additional step of forming the amorphous silicon layer by vacuum deposition, which also makes it very difficult to reuse the glass substrate serving as the support substrate. In addition, the thin-film layers forming the thin film transistor are inorganic films, too. As a result, the inorganic films more fragile and breakable than the organic films are consequently used to protect the thin film transistor, which is formed from the same inorganic films, and hence there is a fear in that the separating layer and the thin film transistor break easily at the time the glass substrate is separated at the separating layer.

The problem of breakage due to fragility is lessened by using an organic layer as the separating layer. It is however a known fact that the organic material rarely has satisfactory transparency and heat resistance both. Specifically, only a few organic materials that have a glass transition temperature Tg of 250° C. or higher, particularly 300° C. or higher, are transparent around a thickness of 10 μm, at which the organic layer exhibits a given level of sturdiness (strength) as a self-standing film, and most organic materials that have this glass transition temperature are yellow-colored at this thickness. Accordingly, while reflective display devices such as electronic paper can use an organic layer as a separating layer, it is difficult to apply an organic separating layer to transmissive liquid crystal display devices and display devices that take out light on the organic layer side, such as bottom emission organic electroluminescent display devices.

### SUMMARY OF THE INVENTION

The present invention provides a method of manufacturing a display device in which a display device having a semiconductor circuit or a display circuit can be fabricated on a substrate by a transfer method.

The present invention also provides a method of manufacturing a display device with which it is easy to reuse a support substrate (for example, a glass substrate or a quartz substrate) on an existing manufacturing line.

A method of manufacturing a display device according to one aspect of the present invention includes:

forming a polymer layer which includes an organic material on a principal surface side of a support substrate;

forming one of a semiconductor circuit and a display circuit on the polymer layer; irradiating the polymer layer from the support substrate side with light having a wavelength that is absorbed in the polymer layer, to thereby separate the polymer layer from the support substrate;

one of thinning and removing the polymer layer; and

adhering a first substrate to one of a surface of the polymer layer and a face where the polymer layer has been provided.

In the method of manufacturing a display device as described above, the polymer layer may have a glass transition temperature of 250° C. or higher.

In the method of manufacturing a display device as described above, the polymer layer may include one selected from polybenzoxazole, polyamide-imide, polyimide, and polyamide.

In the method of manufacturing a display device as described above, the polymer layer disposed on the support substrate may have a thickness of 3 μm or more and 30 μm or less.

In the method of manufacturing a display device as described above, the light having a wavelength that is absorbed in the polymer layer may be light having a wavelength of 200 nm or more and 400 nm or less.

In the method of manufacturing a display device as described above, the light having a wavelength that is absorbed in the polymer layer may be XeCl excimer laser light.

In the method of manufacturing a display device as described above, the first substrate may be a bendable transparent substrate.

In the method of manufacturing a display device as described above, the support substrate may be one of a glass substrate and a quartz substrate.

In the method of manufacturing a display device as described above, the one of thinning and removing the polymer layer may include reducing the polymer layer in thickness to 2 μm or less.

In the method of manufacturing a display device as described above, the semiconductor circuit may be an amorphous silicon thin film transistor.

In the method of manufacturing a display device as described above, the display device may be a liquid crystal display device.

In the method of manufacturing a display device as described above, the display device may be an organic electroluminescent display device.

According to the method of manufacturing a display device described above, the display device having a semiconductor circuit or a display circuit can be fabricated on the substrate by the transfer method. The method also makes it easy to reuse the support substrate (for example, glass substrate or quartz substrate) on the existing manufacturing line.

Other effects of the present invention will become clear by reading the entire description provided herein.

### BRIEF DESCRIPTION OF THE DRAWINGS

In the accompanying drawings:

FIG. 1 is a graph showing an example of the transmission spectrum of a polybenzoxazole layer that is a polymer layer of the present invention;

FIG. 2 is a plan view illustrating the structure of one sub-pixel of a transmissive liquid crystal display panel that is a display device according to a first embodiment of the present invention;

FIG. 3 is a sectional view illustrating a sectional structure that is cut along the line A-A′ of FIG. 2;

FIG. 4 is a sectional view illustrating a sectional structure that is cut along the line B-B′ of FIG. 2;

FIGS. 5A, 5B, 5C, 5D, 5E, 5F, 5G, 5H, and 5I are diagrams illustrating a method of manufacturing a first transparent substrate in the display device that is a liquid crystal display device according to the first embodiment of the present invention;

FIG. 6 is a graph showing an example of the transmission spectrum of the polybenzoxazole layer that is the polymer layer of the present invention at a thickness of 1 μm;

FIGS. 7A, 7B, 7C, 7D, 7E, 7F, 7G, 7H, 7I, and 7J are diagrams illustrating a method of manufacturing a display device that is a liquid crystal display device according to a second embodiment of the present invention;

FIG. 8 is a sectional view illustrating the schematic structures of a thin film transistor portion and a pixel portion in a display device that is a liquid crystal display device according to a third embodiment of the present invention;

FIG. 9 is a sectional view illustrating the schematic structure of the display device that is a liquid crystal display device according to the third embodiment of the present invention;

FIGS. 10A, 10B, 10C, 10D, 10E, 10F, 10G, and 10H are diagrams illustrating a method of manufacturing a first transparent substrate in the display device that is a liquid crystal display device according to the third embodiment of the present invention;

FIGS. 11A, 11B, 11C, 11D, 11E, 11F, 11G, and 11H are diagrams illustrating a method of manufacturing a display device that is a liquid crystal display device according to a fourth embodiment of the present invention;

FIG. 12 is a diagram illustrating the schematic structure of a display device that is a liquid crystal display device according to a fifth embodiment of the present invention, in the form of a sectional view of a region where a thin film transistor is formed;

FIG. 13 is a diagram illustrating the schematic structure of the display device that is a liquid crystal display device according to the fifth embodiment of the present invention, in the form of a sectional view of a region where a pixel is formed;

FIG. 14 is a sectional view illustrating the schematic structure of a display device that is an organic electroluminescent display device according to a sixth embodiment of the present invention;

FIGS. 15A, 15B, 15C, 15D, 15E, and 15F are diagrams illustrating a method of manufacturing the display device that is a organic electroluminescent display device according to the sixth embodiment of the present invention; and

FIG. 16A is a plan view illustrating the schematic structure of a display device that is a liquid crystal display device according to a seventh embodiment of the present invention.

FIG. 16B is an enlarged view of a circular mark A of FIG. 16A.

### DETAILED DESCRIPTION OF THE INVENTION

Display devices according to embodiments of the present invention and methods for manufacturing the display devices are described below with reference to the drawings. In the following description, the same components are denoted by the same reference symbols to avoid a repetitive description.

### 1. Basic Structure and Manufacturing Method of a Display Device of the Invention

### 1.1. Basic Structure of the Display Device

A display device of the present invention is, for example, a liquid crystal display device or an organic electroluminescent display device. The display device of this invention also includes a substrate made of a flexible material that is a polymer material (an insulating substrate). More specifically, the display device of the present invention has an insulating substrate provided with a circuit layer that contains a thin film transistor. In the display device of the present invention, a semiconductor circuit contained in the circuit layer can be an amorphous silicon thin film transistor. The insulating substrate can be a flexible and bendable substrate. The insulating substrate in the present invention is described first.

In case that the display device is a liquid crystal display device, for example, a first substrate and a second substrate which are insulative transparent substrates are opposed to each other across a liquid crystal layer. On the principal surface (the liquid crystal layer, the opposed face) side of the first substrate, a plurality of signal lines (drain lines) and scanning lines (gate lines) intersecting the signal lines are provided to create pixel regions in areas enclosed by the signal lines and the scanning lines. Each pixel region is provided with a pixel electrode, as well as a thin film transistor which reads and controls a gray scale signal applied to the pixel electrode from a relevant signal line. These various lines and components including the thin film transistor are provided in the circuit layer. Components provided on the principal surface (the liquid crystal layer, the opposed face) side of the second substrate include a color filter constituting color display pixels of red (R), green (G), and blue (B), and a black matrix layer.

In addition, for example, the display device can be an organic electroluminescent display device. The organic electroluminescent display device has an insulating first substrate and, on the principal surface side of the first substrate, a plurality of signal lines (drain lines) and scanning lines (gate lines) intersecting the signal lines are provided to create pixel regions in areas enclosed by the signal lines and the scanning lines. Each pixel region is provided with an emitting layer made of a thin organic electroluminescent film, as well as other components including a driver thin film transistor, which controls an electric current supplied to the emitting layer, a switching thin film transistor, which controls the reading of a gray scale signal applied to the driver thin film transistor from a relevant signal line, and a storage capacitor, which keeps the gray scale signal for a given frame period. A layer in which these various lines and components including the thin film transistors are provided is the circuit layer. Organic electroluminescent display devices are roughly divided into a bottom emission type in which light generated in the emitting layer is taken out on the first substrate side and a top emission type in which the generated light is taken out on the principal surface side of the first substrate, namely, the circuit layer side. Bottom emission organic electroluminescent display devices, where light is taken out on the first substrate side, need to use a transparent insulating substrate as the first substrate similarly to in liquid crystal display devices. In organic electroluminescent display devices, the color purity may be improved by taking a top emission structure in which a second substrate corresponding to the first substrate is used, a color filter and other components are formed on the second substrate, and light is taken out through the color filter as in liquid crystal display devices.

In the display device of the present invention, the formation of the circuit layer involves forming the circuit layer on a third substrate, which is a different substrate from the first substrate and serves as a support substrate during manufacture, subsequently separating the circuit layer from the third substrate along with a protecting layer, which contains the circuit layer, and other layers, and adhering these layers to the first substrate via an adhesive layer. Accordingly, the first substrate and the second substrate in the present invention do not need heat resistance, and transparent polymer substrates having a thickness of about 50 μm or more and 500 μm or less are satisfactory as the first substrate and the second substrate. The first substrate and the second substrate can be bendable transparent substrates. The first substrate and the second substrate are not limited to particular bendable polymer substrates, and can be plastics or films, or even very thin glass substrates. Polymer substrates desirable as the first and second substrates transmit light that has a wavelength of 400 nm or more and 800 nm or less at a transmittance of 90% or higher. In the case where the display device uses a color filter in combination with a polymer film as a polymer substrate, the color filter is desirably the same film as the polymer film in order to avoid differences in coefficient of thermal expansion and in stress between a thin film transistor TFT, which is adhered to the polymer film, and the color filter. The polymer film in this case desirably has a heat resistance of about 200° C., which is suitable for the color filter forming process.

In the display device structured as this, the circuit layer is formed on a polymer layer provided on the principal surface side of the third substrate, separated from the third substrate along with the polymer layer, and then adhered to the first substrate via an adhesive layer after thinning or removing the polymer layer.

### 1.2. Substrate Manufacturing Method

Described below is a method of manufacturing a substrate on the side where the circuit layer containing a thin film transistor is provided when the polymer layer is formed. Examples of the third substrate (support substrate) used when the polymer layer is formed include a glass substrate, a quartz substrate, a silicon substrate, and a metal substrate. In the present invention, a transparent substrate such as a glass substrate or a quartz substrate is desirable as the third substrate in the sense that laser light irradiation can be carried out from the rear side. The polymer layer and layers above the polymer layer are ultimately separated from the substrate in the present invention. The substrate is therefore unaffected and can be recycled, which leads to reduction in device manufacture cost.

In the manufacture of the display device of the present invention, the polymer layer is formed first on this third substrate. The polymer layer is formed by creating a thin-film layer on the principal surface side (i.e., the front face) of the third substrate by applying a solution of the polymer described above, or a solution of a precursor of the polymer, through spin-coating or slit-coating. Usually, pre-baking for vaporizing the solvent is performed after the solution is applied by spin-coating or slit-coating. The pre-baking is followed by curing/hard baking at 250° C. or higher in an atmosphere of inert gas such as nitrogen gas, or in vacuum. Baking in the air causes the coloring of the polymer layer through oxidization, and is therefore undesirable. The temperature in the curing/hard baking is set such that the material of the polymer layer does not dissolve, and is desirably higher than the temperature in the subsequent process of forming a semiconductor element that contains a thin film transistor. Specifically, a desirable curing/hard baking temperature is 300° C. or higher and 500° C. or lower.

An inorganic film is desirably formed next on the polymer layer from silicon oxide (SiO), silicon nitride (SiN), silicon oxynitride (SiON), aluminum oxide (AlO), or the like. The inorganic film has a function as a barrier layer which prevents the infiltration of contaminants such as water and oxygen from the polymer layer into the semiconductor element containing a thin film transistor which is provided on the polymer layer. The thickness of the inorganic film is desirably 10 nm or more and 2,000 nm or less, more desirably, 50 nm or more and 500 nm or less. If necessary, a stack of two or more inorganic films may be used instead of a single inorganic film as appropriate. The inorganic film can be formed by a sputtering method, reactive plasma deposition, chemical vapor deposition (CVD), plasma enhanced CVD, or the like. The inorganic film which is formed on the polymer layer which is made of an organic material is desirably formed at a low temperature to minimize damage to (adverse effect over) the polymer layer. Specifically, a more desirable inorganic film is one that can be formed at 100° C. or lower.

In the case where the inorganic film is formed, the semiconductor element containing a thin film transistor is formed as a layer above the inorganic film (on a surface of the inorganic film). In the case where the inorganic film is not formed, the semiconductor element is formed as a layer above the polymer layer (on a surface of the polymer layer). This semiconductor element can have the same structure as that of a semiconductor element formed on a usual substrate (for example, a glass substrate). The usual process in which the temperature is around 300° C. can also be used for this semiconductor element because the polymer layer has high heat resistance.

The forming of the semiconductor element is followed by a process of further forming a liquid crystal or organic electroluminescent display element (display pixel), and then by the separation of the semiconductor element. Alternatively, the semiconductor element may be separated as it is immediately after being formed. The step of separating the semiconductor element is performed with the surface of the semiconductor element protected by a protecting film or the like that is stretched over the formed semiconductor element. The protecting film prevents the breakage of the formed semiconductor element due to stress generated by the detachment of the third substrate, which is a glass substrate or the like. The protecting film is desirably one that can be adhered temporarily and stripped later. Protecting films that satisfy this criterion are those used in the back grinding of a semiconductor, such as “Icros Tape” (product name) by MITSUI CHEMICALS, INC., “Revalpha” (product name) by NITTO DENKO CORPORATION, and “Elegrip Tape” (product name) by TOYO ADTEC CO., LTD. When adhered as a protecting film and then heated, these products by nature are lessened in adhesion or foam and consequently separate, which means that the products can readily be separated as the need arises.

After the protecting film is separated, an alignment film is formed on the exposed surface and a known alignment process such as rubbing is performed. The alignment process is followed by the fixing of the color filter side substrate, which is made from a polymer substrate, and a liquid crystal injection step.

In the present invention, the separation step, which is executed at the stage of the semiconductor element containing a thin film transistor as described above, may instead be performed after the manufacture proceeds to a later step where the injected liquid crystal is made into a cell or an organic electroluminescent element is formed. In this case, when the display device is a liquid crystal display device, the polymer layer is formed on the third substrate and then the semiconductor element is formed on the polymer layer. This semiconductor element, too, has the same structure as that of a semiconductor element formed on a usual substrate (for example, a glass substrate). An alignment layer is then formed on the semiconductor element and a known alignment process such as rubbing is performed. The alignment process is followed by the fixing of the color filter side substrate, which is made from a polymer substrate, and a liquid crystal injection step. The step of separating the third substrate in which the color filter side substrate serves as a support substrate can be put after this step. In the case of an organic electroluminescent element, too, the separation step can be put after the forming of the emitting layer, electrodes, a passivation film, and other components.

In the present invention, the step of separating the polymer layer in which the semiconductor element and the display element are provided from the third substrate desirably contains a step of irradiating the polymer layer with an ultraviolet ray. Although some polymer layer formed on the third substrate can be separated mechanically, it is desirable to sever the bond between the third substrate and the polymer layer by irradiation with an ultraviolet ray in order to reduce damage to the semiconductor element formed on the polymer layer. The ultraviolet ray used here desirably has a wavelength of 200 nm or more and 400 nm or less. Specifically, laser light such as XeCl excimer laser light having a wavelength of 308 nm and KrF excimer laser light having a wavelength of 248 nm, and a third harmonic wave (wavelength: 355 nm) and fourth harmonic wave (wavelength: 266 nm) of a YAG laser (wavelength: 1,064 nm) are desirable because of their high power. Light having a wavelength of 365 nm, 313 nm, or 254 nm which is a bright line of a mercury lamp, an Xe—Hg lamp, or the like can also be used.

When a transparent substrate such as a glass substrate or a quartz substrate is used as the third substrate, in particular, it is desirable to irradiate a face where the transparent substrate is provided, instead of a face where the semiconductor element is formed, with light having a wavelength that is transmitted through the transparent substrate at a transmittance of 90% or higher. The light used here more desirably has a wavelength of 200 nm or more and 380 nm or less. Light in this range can be transmitted efficiently through a quartz substrate or a glass substrate that serves as the third substrate, while being absorbed in the polymer layer. The light also desirably has a wavelength that is transmitted through the polymer layer at that thickness at a transmittance of 10% or lower, more desirably, 5% or lower. This is because, when irradiating the rear face, light having a wavelength that is transmitted through the polymer layer at the thickness set to the polymer layer at a transmittance of 5% or lower is absorbed at the interface between the transparent substrate and a polymer film (a) to cut the bond at the interface, and thus facilitates the separation.

In the present invention, the polymer layer is thinned or removed after the third substrate is separated. The step of thinning or removing the polymer layer can employ etching, asking, polishing, or the like. The polymer layer after the thinning desirably has a transmittance of 90% or higher with respect to light having a wavelength of 400 nm or more and 800 nm or less. While removing the polymer layer completely is an option in the present invention, the polymer layer may instead be reduced in thickness to 2 μm or less for the purpose of preventing the breakage of the element. By thinning the polymer layer in this manner, the transmittance in the visible light range is improved and the structure becomes suitable for a display element of transmissive liquid crystal display devices, bottom emission organic electroluminescent display devices, and other similar display devices. Thinning the polymer layer also gives a small value to retardation (phase difference) of the polymer layer, and therefore is favorable for liquid crystal displays that use a polarizer (polarizing layer).

### 1.3. Polymer Layer

The polymer layer in the present invention is described below. The polymer layer of the present invention is provided in the pixel regions as well, and is therefore desirably a heat-resistant polymer layer high in transparency. Specifically, the polymer layer desirably has a thickness of 3 μm or more and 30 μm or less. More desirably, the polymer layer at this thickness has a transmittance of 50% or higher with respect to visible light having a wavelength of 420 nm or more and 800 nm or less. A desirable polymer layer efficiently absorbs light used in the separation which is described later. Therefore, the polymer layer desirably has a transmittance of 10% or lower with respect to irradiation light used for the separation. Alternatively, the polymer layer desirably has a transmittance of 20% or lower with respect to light having a wavelength of 200 nm or more and 380 nm or less.

In the present invention, the semiconductor element, which contains a thin film transistor and others, and the display element are provided above the polymer layer. The polymer layer is required to have heat resistance because the process temperature for forming the semiconductor element, particularly an amorphous silicon thin film transistor, is usually around 300° C. The glass transition temperature of at least the polymer layer is therefore desirably 250° C. or higher, more desirably, 300° C. or higher. Generally speaking, the coefficient of thermal expansion of a polymer material film rapidly increases once the film's glass transition temperature is exceeded. Some polymer material is warped when the temperature is over the material's glass transition temperature. It is therefore desirable to keep the temperature in the process of forming the semiconductor element from exceeding the glass transition temperature.

In the present invention, the semiconductor element and the display element are formed on the polymer layer, and then separated by using the polymer layer as a separating layer. To avoid the breakage of a thin film transistor TFT layer, which is a semiconductor element layer, during the separation step, the polymer layer desirably has a thickness of 3 μm or more and 30 μm or less. The polymer layer more desirably has a thickness of 5 μm or more and 20 μm or less in order to secure strength in the separation and improve the transmittance in the subsequent steps, and for the purpose of the step of thinning or removing the polymer layer. While the transmittance of the polymer layer portion can be improved by the step of thinning or removing the polymer layer in the present invention, it is basically desirable to use a polymer layer that is high in the transmittance of visible light.

A polymer that has the physical properties described above and that can be used as the polymer layer is desirably one selected from polybenzoxazole (PBO), polyamide-imide (PAI), polyimide (PI), and polyamide (PA). These polymers are generally high in heat resistance and can have a glass transition temperature of 250° C. or higher. Polybenzoxazole, polyamide-imide, polyimide, and polyamide can be used in combination with a cross-linker agent in order to improve heat resistance and, particularly, the glass transition temperature. Cross-linker agents having the following structures can be used. The amount of a cross-linker agent used is 0.1 to 30 wt %, more desirably, 1 to 10 wt %, in relation to the polymer or a precursor of the polymer.

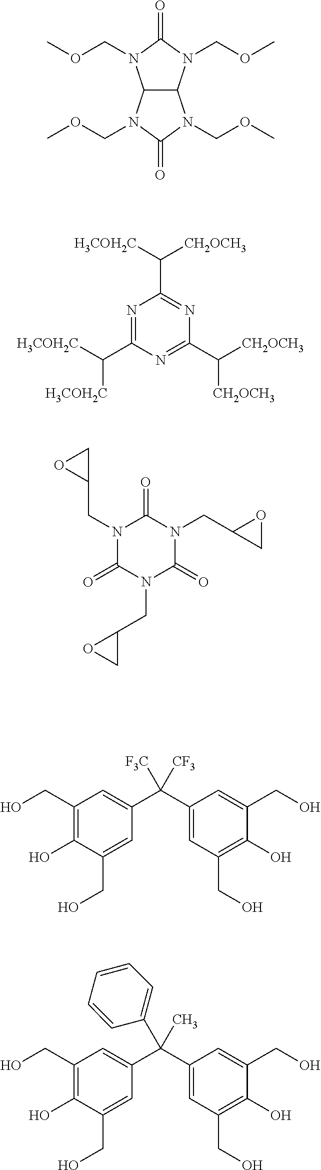

Concrete examples of materials favorable as the polymer layer are given below. Desirable polybenzoxazole is specifically one represented by the following General Formula (1):

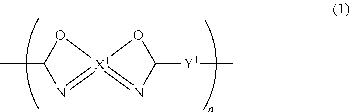

where X¹ represents a quadrivalent aromatic group, Y¹ represents a divalent aromatic group or alicyclic group, and n represents 5 to 10,000.

Polybenzoxazole represented by General Formula (1) is obtained by the cyclodehydration of a corresponding precursor, which is represented by the following General Formula (2), with heat:

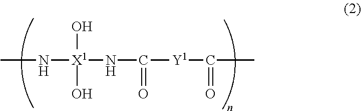

where X¹ represents a quadrivalent aromatic group, Y¹ represents a divalent aromatic group or alicyclic group, and n represents 5 to 10,000.

Desirable polyamide-imide is specifically one containing an alicyclic structure that is represented by the following General Formula (3):

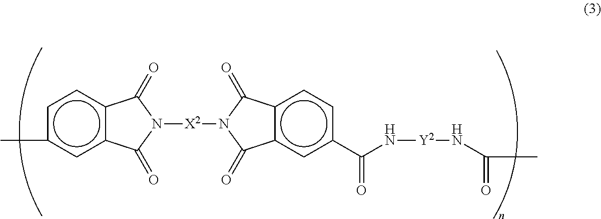

where X² represents a divalent alicyclic group, Y² represents a divalent aromatic group or alicyclic group, and n represents 5 to 10,000.

More desirable polyamide-imide is specifically one that is represented by the following General Formula (4):

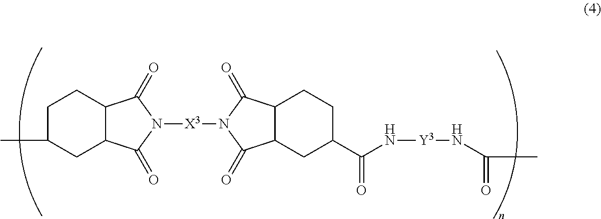

where X³ represents a divalent alicyclic group, Y³ represents a divalent aromatic group or alicyclic group, and n represents 5 to 10,000.

Desirable polyimide is specifically one containing an alicyclic structure that is represented by the following General Formula (5):

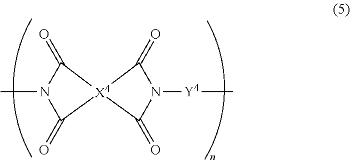

where X⁴ represents a quadrivalent alicyclic group, Y⁴ represents a divalent aromatic group or alicyclic group, and n represents 5 to 10,000.

Polyimide represented by General Formula (5) is desirably obtained by forming a film from polyamic acid, which is a precursor, and then turning the film into polyimide by thermal curing.

Desirable polyamide is specifically one containing an alicyclic structure that is represented by the following General Formula (6):

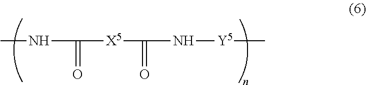

where X⁵ represents a quadrivalent alicyclic group, Y⁵ represents a divalent aromatic group or alicyclic group, and n represents 5 to 10,000.

### 1.4. Example 1

To give an example of a material favorable as a polymer layer of Example 1, a polymer layer formed from polybenzoxazole by the inventors of the present invention is described. A solution was prepared by dissolving 100 parts by weight of a polybenzoxazole precursor that is represented by the following formula (7) and 3 parts by weight of a cross-linker agent that is represented by the following formula (8) in γ-butyrolactone (BLO)/propylene glycol monomethyl ether acetate (PGMEA)=9/1. This solution was applied by spin-coating to a quartz substrate having a thickness of 0.6 mm and serving as the third substrate. The substrate was subjected to pre-baking at 120° C. for three minutes to obtain a coat having a thickness of 12 μm.

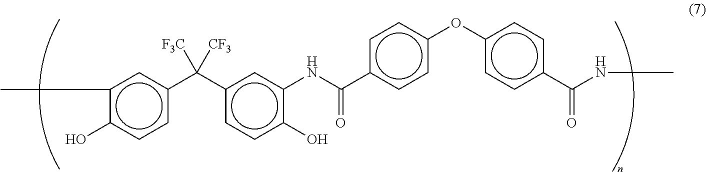

where n represents 5 to 10,000.

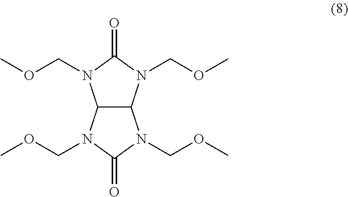

Next, an inert gas oven was used to bake the substrate in a nitrogen atmosphere at 200° C. for thirty minutes, and then curing/hard baking was performed at 350° C. for an hour to obtain a cross-linked polybenzoxazole layer represented by the following formula (9) (the cross link is not shown). The thickness of the cured film was 10 μm and the polymer layer at that point was yellow.

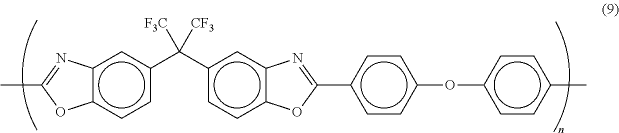

where n represents 5 to 10,000.

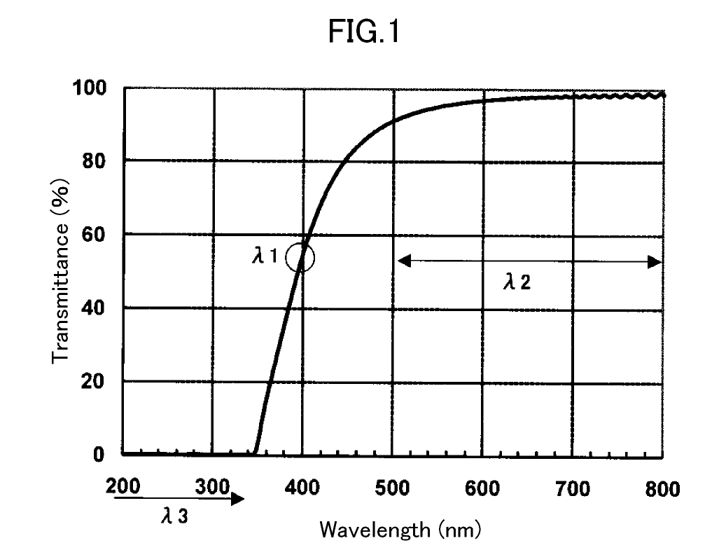

FIG. 1 is a graph showing an example of the transmission spectrum of a cross-linked polybenzoxazole layer that is a polymer layer formed by the procedure described above. The characteristics of this polymer layer are described below. In FIG. 1, the axis of abscissa represents the wavelength (nm) of light and the axis of ordinate represents a transmittance T (%) of light. The transmission spectrum shown in FIG. 1 is that of the polymer layer (cured film) with respect to light in a wavelength range of 200 nm to 800 nm.

As is clear from FIG. 1, the polymer layer formed by the inventors of the present invention has a transmittance of about 50% for a wavelength near 400 nm which is indicated by a circular mark λ1, and has a transmittance of about 80% or higher in a wavelength range of 500 nm to 800 nm which is indicated by an arrow λ2. The transmittance of the polymer layer is 0% for a wavelength equal to or less than 350 nm which is indicated by an arrow λ3, namely, the ultraviolet range, and the polymer layer obviously has characteristics that do not allow the transmission of light having a wavelength of 350 nm or less. From this result, it is understood that the polymer layer formed by the inventors of the present invention has a sufficiently high transmittance in a wavelength range of 500 nm to 800 nm, which is within the visible light range, but has a low transmittance and is consequently yellow-colored in a wavelength range of 400 nm to 500 nm.

The inventors of the present invention next used EMD-WA1000S/W, a product of ESCO, Ltd., to perform thermal desorption spectroscopy on a polybenzoxazole layer (polymer layer) that was created on a silicon substrate by the same procedure as the one described above. It was found as a result that desorption did not occur until 350° C., which was the curing temperature, and that the polymer layer had high heat resistance. The polymer layer was separated from the silicon substrate to measure a glass transition temperature Tg and a coefficient of thermal expansion CTE. The glass transition temperature Tg and the coefficient of thermal expansion CTE were measured with the TMA-120 model, a product of SII NanoTechnology Inc., at a measurement temperature of 30° C. to 300° C. and a temperature programming rate of 5° C./min., in a tensile mode with the load set to 10 g. It was found as a result that the polymer layer had a glass transition temperature of 320° C. and a coefficient of thermal expansion of 50 ppm/K. The inventors of the present invention used, for convenience's sake, a temperature at which the coefficient of thermal expansion CTE changed greatly as the glass transition temperature in this measurement.

First to fifth embodiments deal with the structures and manufacturing methods of liquid crystal display devices and organic electroluminescent display devices that are display devices to which the polymer layer described above is applied. The display devices are described in detail below.

### 2. First Embodiment

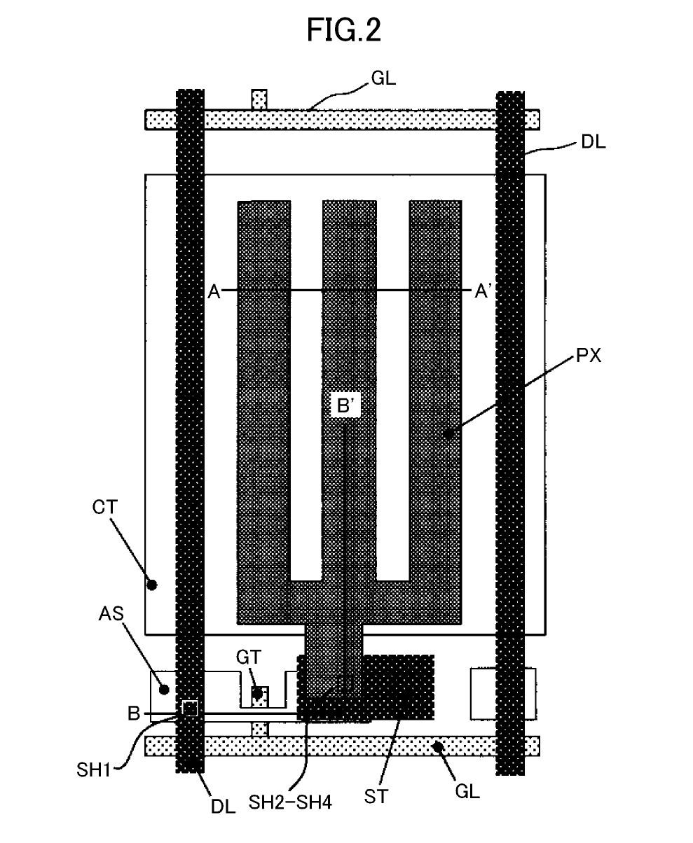

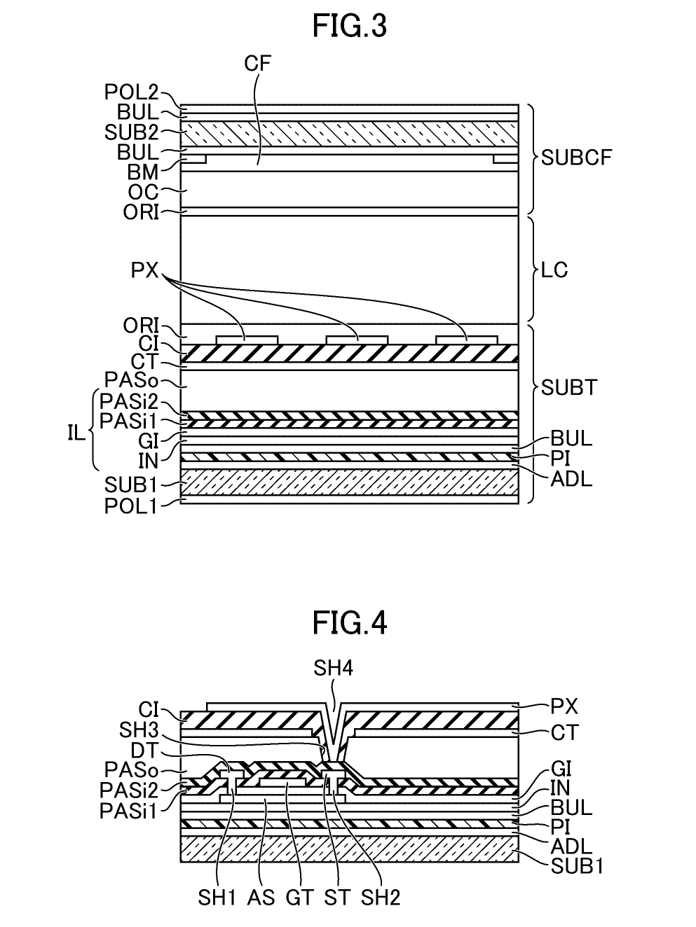

FIG. 2 is a plan view illustrating the structure of one sub-pixel of a transmissive liquid crystal display panel that is a display device according to the first embodiment of the present invention. FIG. 3 is a sectional view illustrating a sectional structure that is cut along the line A-A′ of FIG. 2. FIG. 4 is a sectional view illustrating a sectional structure that is cut along the line B-B′ of FIG. 2. The sectional view of FIG. 4 in particular illustrates a sectional structure on the side of a first transparent substrate SUBT, and a polarizing layer POL1 is omitted from FIG. 4. Symbols X and Y in FIG. 2 represent an X axis and a Y axis, respectively.

### 2.1. Structure

The structure of the liquid crystal display panel of the first embodiment is described below with reference to FIGS. 2 to 4. As illustrated in FIG. 2, the liquid crystal display panel of the first embodiment has, in a not-shown display region, signal lines (hereinafter, referred to as drain lines) DL, which run in a direction Y and are placed side by side in a direction X, and scanning lines (hereinafter, referred to as gate lines) GL, which run in the direction X and are placed side by side in the direction Y. Rectangular regions enclosed by the drain lines DL and the gate lines GL are regions in which pixels are provided, and the pixels are thus arranged in a matrix pattern within a display region AR. Each pixel region is provided with a not-shown color filter of one of red (R), green (G), and blue (B). In the liquid crystal display device of the first embodiment, in particular, an R pixel, a G pixel, and a B pixel that are arranged next to one another in the direction X, namely, a direction in which the gate lines GL run, constitute a unit pixel for color display. However, the structure of the unit pixel for color display is not limited thereto.

The gate lines GL are each provided with a gate electrode GT, which is constituted of a projection protruding on the pixel region side. The gate electrode GT functions as a gate electrode of a thin film transistor TFT which is an active element. In a layer below the gate electrode GT, a semiconductor layer AS (amorphous silicon) is arranged so as to overlap with the gate electrode GT, and this arrangement makes the thin film transistor TFT a top gate transistor. One of the drain lines DL that runs above the semiconductor layer AS partially overlaps with one end of the semiconductor layer AS, with not-shown insulating layers (gate insulating layer and interlayer insulating layer) interposed therebetween. A through hole (contact hole) SH1 is provided in the insulating layers in this overlapping area, and the drain line DL and the semiconductor layer AS are electrically connected via the through hole SH1 to constitute a drain electrode of the thin film transistor TFT. A source electrode ST, on the other hand, is provided in the same layer where the drain line DL is formed which is above the semiconductor layer AS, and partially overlaps with the other end of the semiconductor layer AS. A through hole (contact hole) SH2 is provided in the insulating layers in this overlapping area, and the source electrode ST and the semiconductor layer AS are electrically connected via the through hole SH2. The source electrode ST is also electrically connected to a linear pixel electrode PX via through holes SH3 and SH4, which are provided in the not-shown interlayer insulating layer and a not-shown capacitor insulating layer.

In the liquid crystal display panel of the first embodiment, a planar counter electrode CT which stretches in the direction X over a plurality of pixels is provided in a layer below the pixel electrode PX, with the capacitor insulating layer interposed therebetween. The counter electrode CT of the first embodiment in particular is connected to a not-shown reference signal line at an edge of the liquid crystal display panel. In this manner, an IPS (lateral field) liquid crystal display panel is built in which an electric field having a component parallel to the plane of a transparent substrate where the pixel electrode PX and the counter electrode CT are provided is generated between the electrodes PX and CT, and is used to drive liquid crystal molecules.

In the thus structured liquid crystal display device (panel) of the first embodiment, the first transparent substrate (thin film transistor side substrate: TFT side substrate) SUBT and a second transparent substrate (color filter side substrate: CF side substrate) SUBCF are opposed to each other across a liquid crystal layer LC in each pixel region as illustrated in FIG. 3. In the first embodiment, the front side of the first transparent substrate SUBT, namely, the top side in FIG. 3, is the viewer side.

The second transparent substrate SUBCF includes a second substrate SUB2, which is a transparent plastic substrate, and barrier layers BUL are provided on the top and bottom faces, namely, the liquid crystal layer side and the rear side, of the second substrate SUB2. On the liquid crystal layer side of the second substrate SUB2, the barrier layer BUL, a black matrix layer BM, a color filter layer CF, an over-coating layer OC, and an alignment layer ORI are provided in order from the second substrate SUB2 toward the liquid crystal layer LC. On the outer side, namely, the viewer side, of the second substrate SUB2, the barrier layer BUL and a polarizing layer POL2 are provided.

The first transparent substrate SUBT includes a first substrate SUB1, which is a transparent plastic substrate. On the liquid crystal layer side, namely, the principal surface side, of the first substrate SUB1, an adhesive layer ADL, the polymer layer (heat-resistant polymer layer) described above which is denoted by PI, another barrier layer BUL, an insulating layer IL, an interlayer insulating layer PASo, a transparent electrode CT which functions as a counter electrode, a transparent insulating layer CI which functions as a capacitor insulating layer, the pixel electrode PX, and another alignment layer ORI are provided in order from the first substrate SUB1 toward the liquid crystal layer LC. On the outer side of the first substrate SUB1, namely, the side of a not-shown backlight unit, a polarizing layer POL1 is provided. The insulating layer IL can include a base layer IN, which is, for example, a laminate of a silicon nitride (SiN) layer and a silicon oxide (SiO₂) layer, a gate insulating layer GI, which is made of, for example, SiO₂, an interlayer insulating layer PASi1, which is made of SiO₂, SiN, or the like, and an interlayer insulating layer PASi2, which is made of SiO₂, SiN, or the like. The barrier layer BUL and the base layer IN, which are separate thin films in this embodiment, may be a single thin film that serves a dual purpose.

As illustrated in FIG. 4, in a region where the thin film transistor is formed, the adhesive layer ADL, the polymer layer (heat-resistant polymer layer) PI, the barrier layer BUL, and the base layer IN are provided on the liquid crystal layer side, namely, the principal surface side, of the first substrate SUB1 in order from the first substrate SUB1 toward the liquid crystal layer LC. The semiconductor layer AS is provided on the top face of (as a layer above) the base layer IN, and at least a display region containing the top face of the semiconductor layer AS is covered with the gate insulating layer GI. The gate electrode GT which extends from the relevant gate line GL is provided in an area above the gate insulating layer GI that overlaps with the semiconductor layer AS. The interlayer insulating layer PASi1 is provided on the top face of the gate electrode GT. A common signal line may be provided in the same layer as the gate electrode GT in an area at an edge of the liquid crystal display panel of the first embodiment.

In the liquid crystal display device of the first embodiment, the through holes SH1 and SH2 which pierce the interlayer insulating layer PASi1 and the gate insulating layer and reach the semiconductor layer AS are provided at two points opposed to each other across the gate electrode GT when the first substrate SUB1 is viewed in plan view. The through hole SH1 is positioned so as to overlap with a region where the drain line DL is formed, and the through hole SH2 is positioned so as to overlap with a region where a thin-film layer to serve as the source electrode ST is formed. With this structure, the drain line DL is connected to the semiconductor layer AS to form the drain electrode of the thin film transistor TFT, and the source electrode ST, which is provided in the same layer as the drain line DL, too is connected to the semiconductor layer AS. On top of the drain line DL and the source electrode ST, the interlayer insulating layer PASi2 is provided, and the interlayer insulating layer PASo is provided thereon to cover the interlayer insulating layer PASi2. The interlayer insulating layer PASo is an organic insulating layer such as an acrylic resin layer, and levels substrate surface irregularities caused by forming the thin film transistor TFT.

Provided on top of the interlayer insulating layer PASo is the counter electrode CT, which is made from a transparent conductive film (for example, ITO: indium tin oxide or ZnO: zinc oxide), and the transparent insulating layer CI is provided thereon so as to cover the counter electrode CT. The linear pixel electrode PX made of a transparent electrode material is provided on the top face of the transparent insulating layer CI. In the liquid crystal display panel of the first embodiment, a through hole SH3 is provided which pierces the interlayer insulating layer PASi2 and the interlayer insulating layer PASo and reaches the surface of the source electrode ST. The transparent insulating layer CI which covers the top face of the counter electrode CT or of the interlayer insulating layer PASo is also provided on the side walls and bottom of the through hole SH3. At the bottom of the through hole SH3, a through hole SH4 is provided in the transparent insulating layer CI and pierces the transparent insulating layer CI to expose the surface of the source electrode ST. The pixel electrode PX is electrically connected to the source electrode ST via the two through holes SH3 and SH4. With this structure, a video signal is written to the pixel electrode PX and a gray scale signal is retained in conjunction with the on/off operation of the thin film transistor TFT. In other words, a video signal is written to the pixel electrode PX from the drain line DL via the thin film transistor TFT, which is an active element driven by the gate line GL. The writing of a video signal controls the transmission amount of light emitted from the backlight unit in the respective pixels, and an image is displayed as a result. In the liquid crystal display device of the first embodiment, the attenuation of light in the visible light range that is emitted from the backlight unit is greatly reduced in the polymer layer PI, which is placed along the transmission path of the light emitted from the backlight unit on the rear side of the first substrate SUB1. The lowering of luminance due to the forming of the polymer layer PI is accordingly reduced.

### 2.2. Manufacturing Method

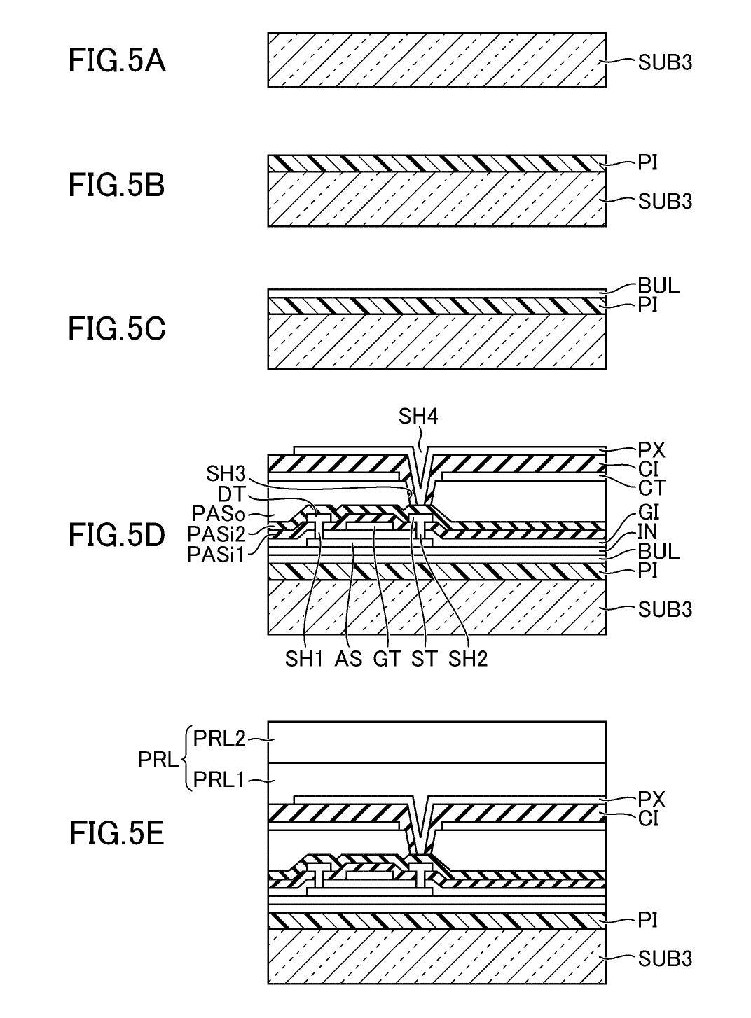

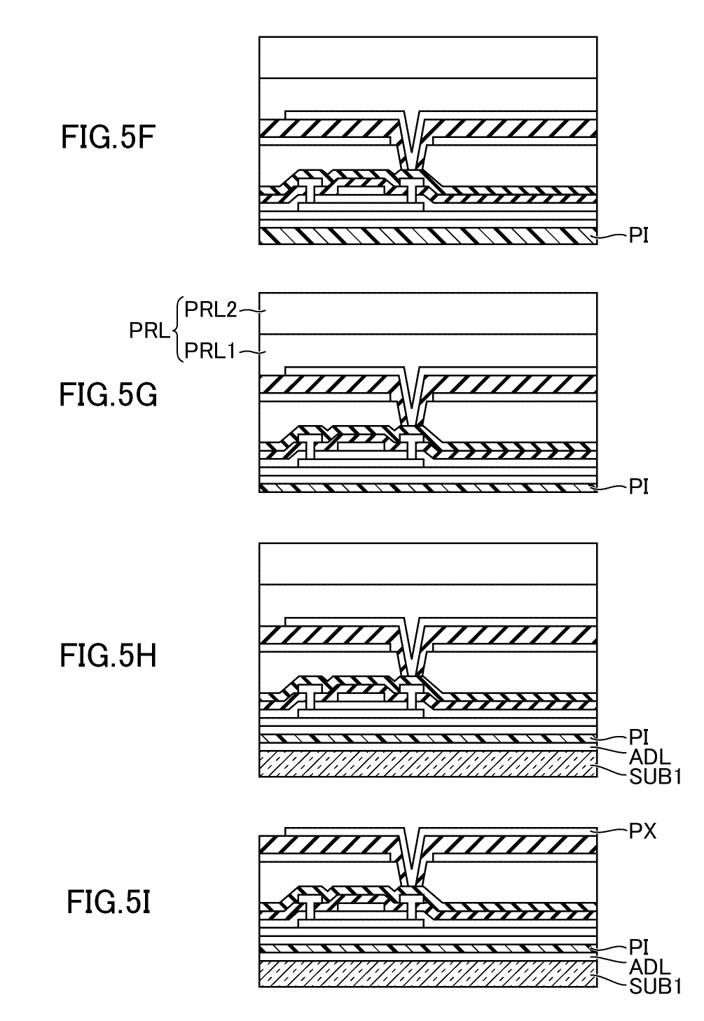

FIGS. 5A, 5B, 5C, 5D, 5E, 5F, 5G, 5H, and 51 are diagrams illustrating a method of manufacturing the first transparent substrate in the display device that is a liquid crystal display device according to the first embodiment of the present invention. A method of manufacturing the liquid crystal display device of the first embodiment is described below with reference to FIGS. 5A to 5I. The structures and forming methods of the thin film transistor TFT and the components provided above the thin film transistor TFT, such as the electrodes PX and CT, are the same as those conventionally employed. The following is therefore a detailed description of the polymer layer PI, which is a feature of the present invention.

### 2.2.1. Step 1-1 (FIGS. 5A and 5B)

As illustrated in FIG. 5A, a transparent glass substrate is used as a third substrate SUB3 in view of the fact that a transparent glass substrate allows laser light irradiation from the rear side and can be recycled. Other substrates than a glass substrate, such as a quartz substrate, a silicon substrate, and a metal substrate, may be used as the third substrate SUB3 as described above. The third substrate SUB3 is desirably a transparent substrate such as a glass substrate or a quartz substrate in the sense that a transparent substrate allows laser light irradiation from the rear side as described later. The polymer layer and layers above the polymer layer are ultimately separated from the substrate, and the substrate is therefore unaffected and can be recycled, which leads to reduction in device manufacture cost.

First, as illustrated in FIG. 5B, the polymer layer (heat-resistant polymer layer) PI is formed to a thickness of 10 μm on the principal surface side (the top face in the drawing) of the third substrate SUB3 from a coat of a heat-resistant polymer of Example 1 that is represented by Formula (9). The curing conditions and the like in this step are as described in Example 1.

### 2.2.2. Step 1-2 (FIG. 5C)

Next, the barrier layer BUL is formed on the polymer layer PI. As the barrier layer BUL, an SiON film is formed to a thickness of 100 nm at room temperature with an ICP-CVD system (ICP stands for Inductive Coupled Plasma).

### 2.2.3. Step 1-3 (FIG. 5D)

Next, the thin film transistor TFT, the pixel electrode PX, and other necessary components of a pixel are formed on the barrier layer BUL by a known deposition method. In the first embodiment, the base layer IN is formed first on the barrier layer BUL. On the base layer IN, there are formed: the semiconductor layer AS; the gate insulating layer GI; the gate electrode GT; the interlayer insulating layer PASi1; a layer for forming the drain line DL, which doubles as the drain electrode DT, and the source electrode ST; the interlayer insulating layer PASi2; and the interlayer insulating layer PASo in order. The counter electrode CT which has a planar shape is formed next on the interlayer insulating layer PASo from a transparent electrode material. The through hole SH3 which exposes the top face of the source electrode ST is formed in the interlayer insulating layer PASi2 and the interlayer insulating layer PASo at this point. Thereafter, the transparent insulating layer CI is formed and the through hole SH4 which exposes the top face of the source electrode ST is formed in the transparent insulating layer CI. The linear pixel electrode PX is then formed on the transparent insulating layer CI from a transparent electrode material, and electrically connected to the source electrode ST via the through hole SH4. The circuit layer is thus formed.

### 2.2.4. Step 1-4 (FIG. 5E)

Next, on the circuit layer supported by the third substrate SUB3, a protecting layer PRL which is constituted of an adhesive layer PRL1 and a holding layer PRL2 is adhered temporarily. This structure prevents the breakage of the circuit layer portion containing the thin film transistor TFT due to stress when the third substrate SUB3 is separated in a later step. In short, the first embodiment prevents the breakage of the circuit layer portion by supporting the circuit layer portion with the protecting layer PRL. The protecting layer PRL is, as described in Example 1, a protecting film used in the back grinding of a semiconductor, such as “Icros Tape” (product name) by MITSUI CHEMICALS, INC. or “Revalpha” (product name) by NITTO DENKO CORPORATION.

### 2.2.5. Step 1-5 (FIG. 5F)

Next, the polymer layer PI is irradiated with Xe—Cl excimer laser light having a wavelength of 308 nm from the rear side of the third substrate SUB3 which is a glass substrate, namely, the side where the circuit layer is not provided. As shown in the graph of FIG. 1, the transmittance of the heat-resistant polymer layer PI is such that light having a wavelength of 308 nm is absorbed efficiently, and accordingly, the absorption lessens the tight adhesion at the interface between the third substrate SUB3 and the heat-resistant transparent polymer layer PI, with the result that the third substrate SUB3 is separated. The tight adhesion is lessened by fifty shots of exposure at an irradiation dose of 150 mJ/cm²/pulse. In addition, because the circuit layer where the thin film transistor is provided is sandwiched to be held between the heat-resistant polymer layer PI, which has a thickness of 10 μm, and the protecting layer PRL, the circuit layer containing the thin film transistor TFT can be separated without being broken when the third substrate is separated. The polymer layer PI in the first embodiment is the polymer layer described in Example 1, which means that the polymer layer can be separated by letting the polymer layer absorb Xe—Cl excimer laser light that has a wavelength of 308 nm. In the case where the polymer layer PI is formed from other polymer materials than polybenzoxazole (PBO), polyamide-imide (PAI), polyimide (PI), and polyamide (PA), the irradiation conditions are modified to suit the employed polymer material.

### 2.2.6. Step 1-6 (FIG. 5G)

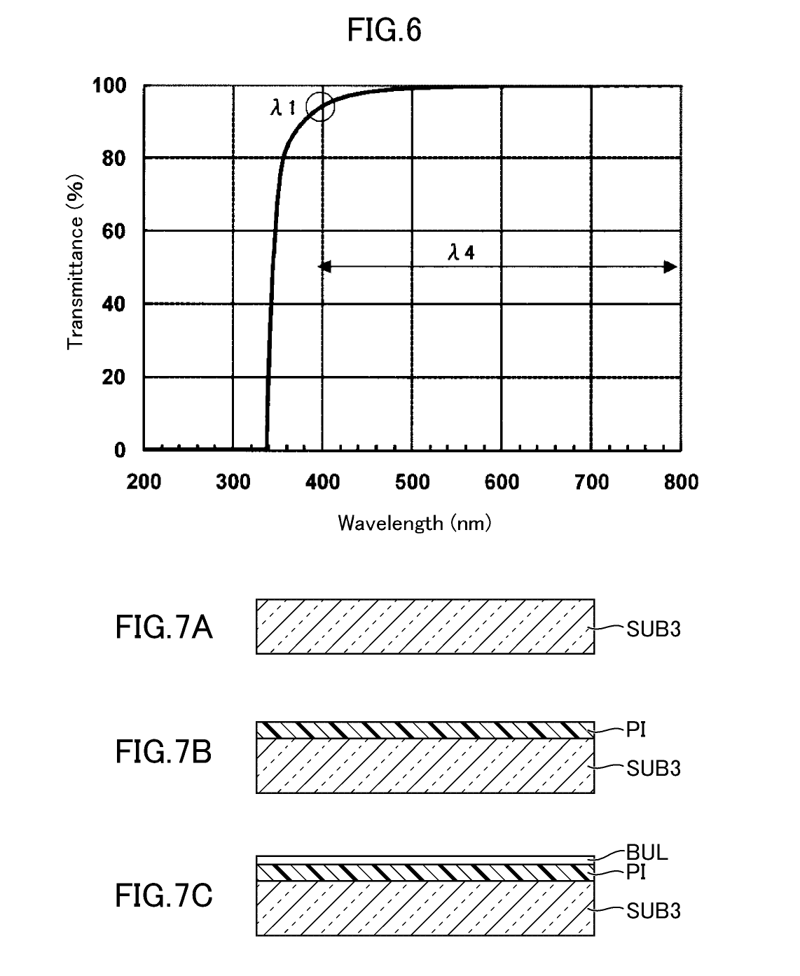

The heat-resistant polymer layer PI is next asked, to thereby reduce the thickness of the heat-resistant polymer layer PI from the initial thickness, 10 μm, to 1 μm. This improves the transmittance. FIG. 6 is a graph showing the transmittance that is observed when the heat-resistant polymer layer PI alone is ashed to a thickness of 1 μm. As is clear from FIG. 6, the transmittance of the polymer layer PI in a wavelength range of 400 nm to 800 nm which is indicated by an arrow λ4 is 90% or higher, thereby making the heat-resistant polymer layer PI transparent. The asking of the heat-resistant polymer layer PI, too, does not break the circuit layer containing the thin film transistor TFT which is formed from an inorganic material, because the heat-resistant polymer layer PI and the protecting layer PRL sandwich the circuit layer.

### 2.2.7. Step 1-7 (FIG. 5H)

Next, the transparent adhesive ADL is used to adhere the first substrate SUB1 which is a plastic film to the side where the separated third substrate SUB3 has been adhered, namely, the rear side of the ashed polymer layer PI. That is, the first substrate SUB1 is adhered on the exposed surface of the polymer layer PI with the transparent adhesive ADL therebetween. The first substrate SUB1 which is a plastic film is thus prepared as a substrate.

### 2.2.8. Step 1-8 (FIG. 5I)

The protecting layer PRL which has been adhered temporarily is separated next. In the case where “Icros Tape” (product name) or “Revalpha” (product name) is used as the protecting layer PRL, the adhesion amount (adhesion) of the adhesive layer PRL1 is easily reduced by heating, and the holding layer PRL2 is readily separated along with the adhesive layer PRL1. As a result, the first transparent substrate SUBT is completed in which the thin film transistor TFT is transferred to the plastic film serving as the first substrate SUB1 without being turned upside down and the circuit layer is provided on the first substrate SUB1.

Thereafter, liquid crystal LC is injected between the first transparent substrate SUBT and the second transparent substrate SUBCF, where the color filter CF and the black matrix layer BM are provided on (the liquid crystal side of) the second substrate SUB2 formed by a known method. The second transparent substrate SUBCF and the first transparent substrate SUBT are fixed to each other with a sealing material, thereby completing the liquid crystal display panel, as shown in FIG. 3. A backlight unit and the like are attached to this liquid crystal display panel to obtain a liquid crystal display device. The second transparent substrate SUBCF uses, for example, a plastic substrate having a thickness of 100 μm as the second substrate SUB2. Barrier layers each having a thickness of 100 nm are formed from SiON on the principal surface side of the second substrate SUB2 and the side of the second substrate SUB2 that is opposite (the rear side, the viewer side) from the principal surface side. This is used as a substrate member. The black matrix layer BM and RGB layers of the color filter CF are then formed on the principal surface side of the second substrate SUB2. The color filter portion includes the over-coating layer and the alignment layer.

As has been described, in the method of manufacturing the first transparent substrate SUBT in the liquid crystal display device of the first embodiment, the polymer layer PI which has heat resistance and high transmittance in the visible light range and which is made of the polymer material described in Example 1 and functions as a separating layer is formed on the third substrate SUB3 serving as a support substrate, and then the circuit layer is formed above the polymer layer PI with the barrier layer BUL interposed therebetween. Next, the protecting layer PRL is temporarily adhered to the top face of the circuit layer, and the polymer layer PI is then irradiated with laser light having a wavelength of 200 nm or more and 400 nm or less from the side of the third substrate SUB3. The laser light is absorbed in the polymer layer PI, to thereby separate the third substrate SUB3 from the polymer layer PI on which the circuit layer is provided. Next, the polymer layer PI is ashed from the separation side, thereby being reduced in thickness from 10 μm, which is the thickness of the polymer layer PI at the time of formation, to 1 μm. After this thinning of the polymer layer PI, the first substrate SUB1 is adhered to the ashed side of the polymer layer PI with a transparent adhesive, and the protecting layer PRL which has been adhered temporarily is subsequently separated. After the protecting layer PRL is separated, the alignment layer is formed by deposition to complete the first transparent substrate SUBT. Liquid crystal LC is injected between the first transparent substrate SUBT and the second transparent substrate SUBCF, and the substrates are fixed to each other to obtain a liquid crystal display device, as shown in FIG. 3. As the polymer layer PI in the first embodiment, the polybenzoxazole (PBO) described in Example 1 is chosen out of polybenzoxazole (PBO), polyamide-imide (PAI), polyimide (PI), and polyamide (PA), which can be used in combination with a cross-linker agent in order to improve the glass transition temperature. The polymer layer PI is formed on the third substrate SUB3 to a thickness of 3 μm or more and 30 μm or less. As a result, when the polymer layer PI on which the circuit layer is provided is separated from the third substrate SUB3, the thin film transistor and other components that constitute the circuit layer are prevented from breaking. In addition, because a glass substrate is used as the third substrate SUB3 and the polymer layer PI is used as a separating layer, the third substrate SUB3 can easily be reused in a conventional manufacture system. Further, in the method of manufacturing the first transparent substrate of the liquid crystal display device of the first embodiment, where the polymer layer PI of Example 1 formed on the third substrate SUB3 is separated from the third substrate SUB3 and then thinned and adhered to the first substrate SUB1, the transmittance of light emitted from a backlight unit is improved despite the use of the heat-resistant polymer layer PI.

### 3. Second Embodiment

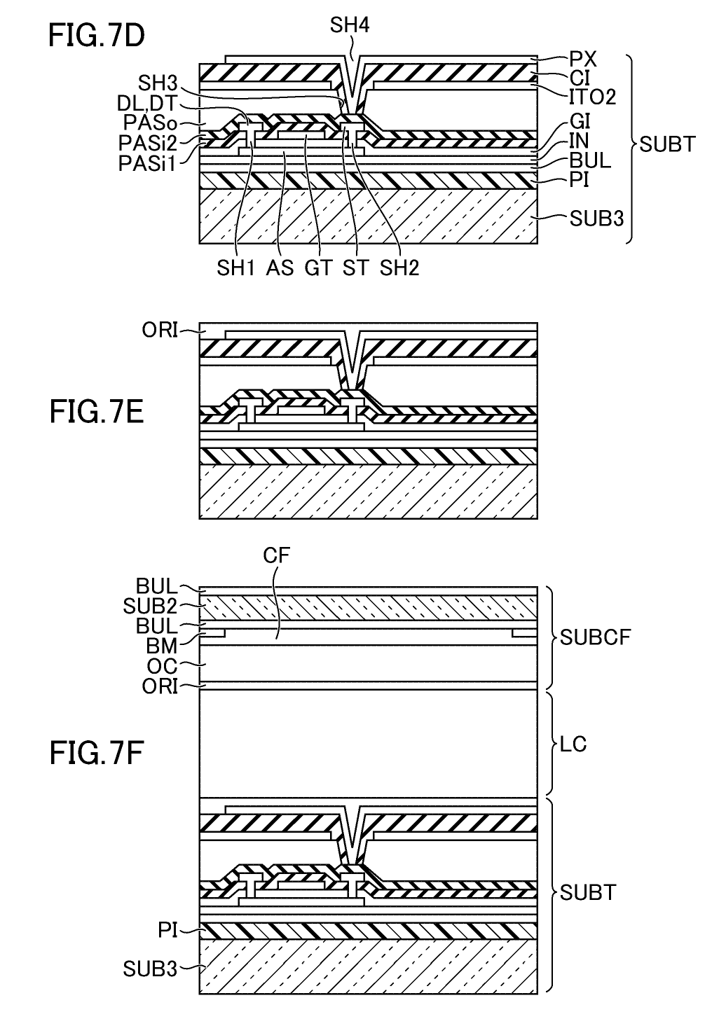

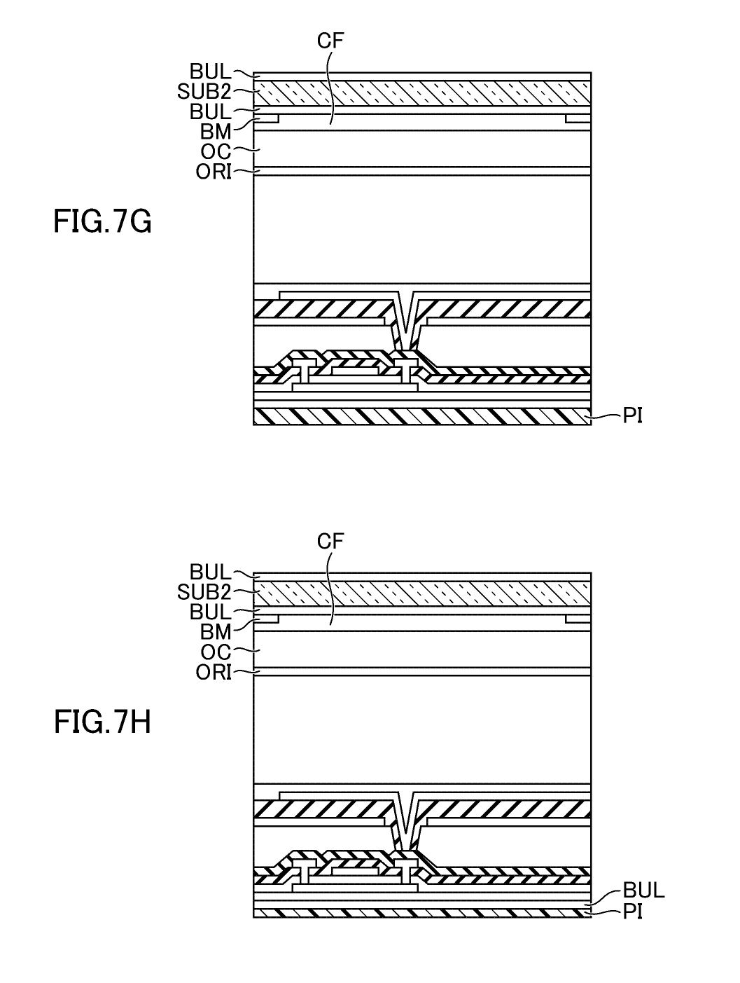

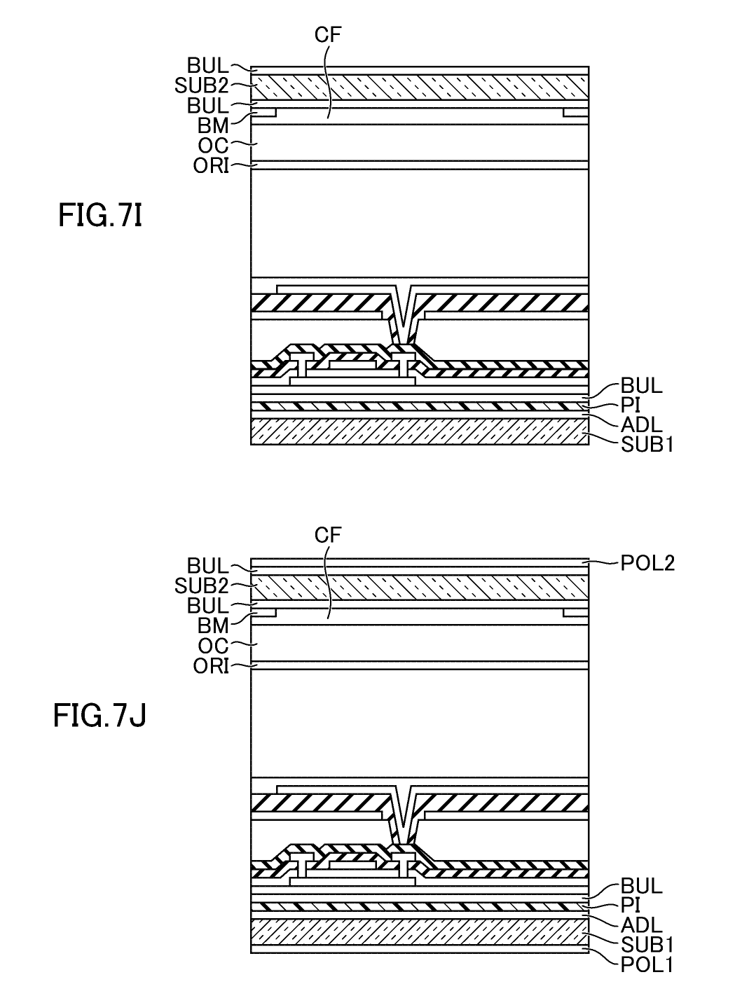

A display device of the second embodiment has the same structure as that of the liquid crystal display device of the first embodiment, but the structure is manufactured by a different method. FIGS. 7A, 7B, 7C, 7D, 7E, 7F, 7G, 7H, 7I, and 7J are diagrams illustrating a method of manufacturing a display device that is a liquid crystal display device according to the second embodiment of the present invention. The method of manufacturing the liquid crystal display device (liquid crystal display panel) of the second embodiment is described in detail below with reference to FIGS. 7A to 7J. In the manufacturing method of the second embodiment, the structure is the same as in the first embodiment except that the second transparent substrate SUBCF is used as a supporting member when the third substrate SUB3 is separated. The following detailed description focuses on the polymer layer PI, which is a feature of the present invention, and the forming of the second transparent substrate SUBCF.

### 3.1. Manufacturing Method

### 3.1.1. Step 2-1 (FIGS. 7A and 7B)

A transparent glass substrate is used as the third substrate SUB3 as in Step 1-1 described above. Similarly to the first embodiment, this allows the recycle of the substrate and lowers the device manufacture cost. As illustrated in FIG. 7B, the polymer layer (heat-resistant polymer layer) PI is formed to a thickness of 15 μm on the principal surface side (top face in the drawing) of the third substrate SUB3 from a coat of the heat-resistant polymer described in Example 1.

### 3.2.1. Step 2-2 (FIG. 7C)

Next, as in Step 1-2 described above, the barrier layer BUL is formed on the polymer layer PI. As the barrier layer BUL, an SiON film is formed to a thickness of 100 nm at room temperature with an ICP-CVD system.

### 3.1.3. Step 2-3 (FIG. 7D)

Next, as in Step 1-3 described above, the thin film transistor TFT, the pixel electrode PX, and other necessary components of a pixel are formed on the barrier layer BUL by a known deposition method. In the second embodiment, too, the circuit layer is formed on the polymer layer PI, which is formed on the third substrate SUB3, by sequentially forming on the barrier layer BUL: the base layer IN; the semiconductor layer AS; the gate insulating layer GI; the gate electrode GT; the interlayer insulating layer PASi1; the layer for forming the drain line DL, which doubles as the drain electrode DT, and the source electrode ST; the interlayer insulating layer PASi2; the interlayer insulating layer PASo; the counter electrode CT; the transparent insulating layer CI; and the pixel electrode PX.

### 3.1.4. Step 2-4 (FIG. 7E)

Next, the known alignment film ORI is formed on the liquid crystal side of the substrate on which the circuit layer is formed, and a known rubbing process is then performed.

### 3.1.5. Step 2-5 (FIG. 7F)

As in the first embodiment, the barrier layers BUL each having a thickness of 100 nm are formed from SiON on the principal surface side (i.e., the liquid crystal side) of the second substrate SUB2, which is a plastic substrate having a thickness of 100 μm, and the side of the second substrate SUB2 that is opposite from the principal surface side. This is used as a substrate. On the principal surface side of the second substrate SUB2 where the barrier layer BUL is formed, the black matrix layer BM and RGB thin-film layers of the color filter CF are formed by a known method. The over-coating layer OC and the alignment layer ORI are further formed thereon to complete the second transparent substrate SUBCF.

Next, the second transparent substrate SUBCF and the third substrate SUB3 which has the circuit layer formed in Step 2-4 are fixed to each other with a sealing material, with the alignment layer ORI of the second transparent substrate SUBCF and the alignment layer ORI of the third substrate SUB3 opposed to each other. When fixing the substrates, liquid crystal LC is injected between the second transparent substrate SUBCF and the third substrate SUB3, and beads spacers are placed in the liquid crystal layer LC.

### 3.1.6. Step 2-6 (FIG. 7G)

Next, as in Step 1-5, the polymer layer PI is irradiated with Xe—Cl excimer laser light having a wavelength of 308 nm from the rear side of the third substrate SUB3, which is a glass substrate (the side where the circuit layer is not provided). The heat-resistant polymer layer PI efficiently absorbs the light having a wavelength of 308 nm. The absorption lessens the tight adhesion at the interface between the third substrate SUB3 and the heat-resistant transparent polymer layer PI, with the result that the third substrate SUB3 is separated easily. In the manufacturing method of the second embodiment, where the heat-resistant polymer layer PI is 15 μm in thickness and the second transparent substrate SUBCF is fixed, the circuit layer in which the thin film transistor TFT and other components are provided is supported by the polymer layer PI and the second transparent substrate SUBCF. As a result, the third substrate SUB3 can be separated from the polymer layer PI at the interface between the third substrate SUB3 and the polymer layer PI without damaging the circuit layer.

### 3.1.7. Step 2-7 (FIG. 7H)

Next, as in Step 1-6, the heat-resistant polymer layer PI is asked to reduce the thickness of the heat-resistant polymer layer PI from the initial thickness, 15 μm, to 1.4 μm. The transmittance is thus improved.

### 3.1.8. Step 2-8 (FIG. 7I)

Next, as in Step 1-7, the transparent adhesive ADL is used to adhere another substrate, namely, the first substrate SUB1 which is a plastic film, to the surface of the polymer layer PI on the side from which the third substrate SUB3 has been separated (namely, the rear side of the polymer layer PI).

### 3.1.9. Step 2-9 (FIG. 7J)

The polarizing layers POL1 and POL2 are then adhered to the top and the bottom to obtain a liquid crystal display panel that includes, as the first transparent substrate SUBT, the first substrate SUB1 which is a plastic film. Thereafter, a not-shown backlight unit is disposed on the rear side of the liquid crystal display panel to obtain a liquid crystal display device.

### 3.2. Characteristics

As has been described, in the method of manufacturing the first transparent substrate SUBT in the liquid crystal display device of the second embodiment, the polymer layer PI which is made of the polymer material described in Example 1 and functions as a separating layer is formed on the third substrate SUB3 serving as a support substrate. Thereafter, the circuit layer, the alignment layer, and others are formed above the polymer layer PI with the barrier layer BUL interposed therebetween. Liquid crystal LC is then injected between the third substrate SUB3 and the second transparent substrate SUBCF. After the substrates are fixed to each other, the polymer layer PI is irradiated with laser light having a wavelength of 200 nm or more and 400 nm or less from the side of the third substrate SUB3. The laser light is absorbed in the polymer layer PI to separate the third substrate SUB3 at the interface between the polymer layer PI and the third substrate SUB3. The polymer layer PI is subsequently thinned, and the first substrate SUB1 is adhered to the polymer layer PI to obtain a liquid crystal display panel. The second embodiment, too, chooses as the polymer layer PI the polybenzoxazole (PBO) described in Example 1 out of polybenzoxazole (PBO), polyamide-imide (PAI), polyimide (PI), and polyamide (PA), which can be used in combination with a cross-linker agent in order to improve the glass transition temperature. The polymer layer PI is formed on the third substrate SUB3 to a thickness of 3 μm or more and 30 μm or less. The same effects as those in the liquid crystal display device manufacturing method of the first embodiment are thus obtained. Moreover, the second embodiment, where the circuit layer is protected by the second transparent substrate SUBCF and the polymer layer PI against damage from stress when the third substrate SUB3 is separated from the polymer layer PI, has a special effect in that the number of steps in the manufacture of a liquid crystal display device is smaller than in the first embodiment.

### 4. Third Embodiment

### 4.1. Overall Structure

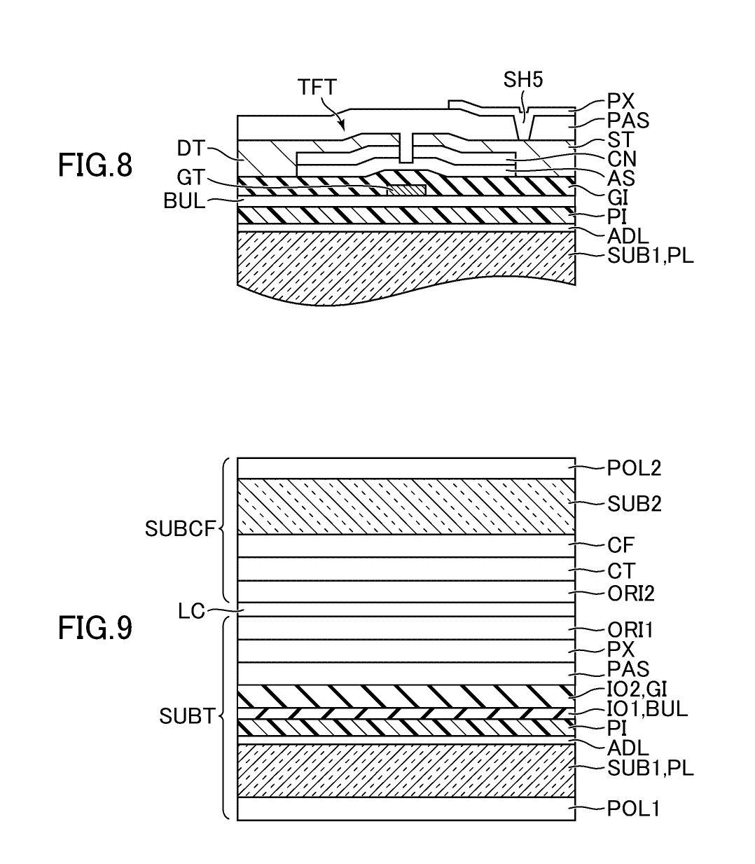

FIG. 8 is a sectional view illustrating the schematic structures of a thin film transistor portion and a pixel portion in a display device that is a liquid crystal display device according to the third embodiment of the present invention. FIG. 9 is a sectional view illustrating the schematic structure of the display device that is a liquid crystal display device that is the display device according to the third embodiment of the present invention. The sectional view of FIG. 9 in particular illustrates a pixel region of the liquid crystal display device of the third embodiment. The liquid crystal display device of the third embodiment is an application of the present invention to a VA or TN (so-called vertical field) liquid crystal display device in which the counter electrode is provided on the side of the second substrate SUB2, namely, the second transparent substrate SUBCF, and an electric field for driving liquid crystal molecules is applied in a direction in which the first transparent substrate SUBT and the second transparent substrate SUBCF are disposed (vertical direction). Note that, the liquid crystal display device of the third embodiment is structured the same way as in the first embodiment except for the structure of the circuit layer which contains the thin film transistor and pixels. Therefore, the following is mainly a detailed description of the structure of the circuit layer.

In the liquid crystal display device of the third embodiment, too, the thin film transistor TFT is provided on the top face of the first substrate SUB1. The thin film transistor TFT can be a switching element for selecting a row of pixels out of pixels arranged in a matrix pattern, or a switching element of a pixel driver circuit provided in the periphery of the display portion, which is an aggregation of the pixels. The thin film transistor TFT can be a laminate in which a patterned conductive layer, semiconductor layer, and insulating layer are stacked in a given order.

As illustrated in FIG. 8, on the first transparent substrate side where the thin film transistor TFT and other components are provided, the polymer layer PI is fixed via the adhesive layer ADL to the top face of the first substrate SUB1, which is made of a polymer such as a plastic film. The barrier layer BUL is provided on the polymer layer PI, and the gate electrode GT is provided on the barrier layer BUL. The gate electrode GT may double as a not-shown gate line, for example, or an extension extended from the gate line may be used as the gate electrode GT. The gate insulating layer GI is provided on the gate electrode GT. On top of the gate insulating layer GI, the island-like semiconductor layer AS and a contact layer CN, which is heavily doped with n-type impurities, are provided in an area that overlaps with the gate electrode GT, and stretch across the gate electrode GT. In the third embodiment, a concave portion is provided which pierces the contact layer CN and creates a hollow in apart of the semiconductor layer AS. The drain electrode DT and the source electrode ST are provided on the contact layer CN and are opposed to each other across the concave portion. The thin film transistor TFT is thus completed. By forming the contact layer CN at the interface between the semiconductor layer AS and the drain electrode DT and at the interface between the semiconductor layer AS and the source electrode ST in this manner, the electric resistance is reduced in the third embodiment. In the third embodiment, too, not-shown drain lines and other components are formed at the time the source electrode ST and the drain electrode DT are formed. The thus structured thin film transistor TFT is covered with a protecting layer PAS. The protecting layer PAS is made from, for example, a silicon nitride film or a polymer. The pixel electrode PX is provided on the protecting layer PAS. A through hole SH5 is provided in the protecting layer PAS to electrically connect the source electrode ST and the pixel electrode PX.

The liquid crystal display panel having this thin film transistor TFT includes, as illustrated in FIG. 9, the first transparent substrate (so-called TFT substrate) SUBT and the second transparent substrate (so-called filter substrate) SUBCF which are arranged to sandwich the liquid crystal LC. The first transparent substrate SUBT includes the first substrate SUB1, which is a polymer member such as a plastic film. On the principal surface of the first substrate SUB1, namely, a face of the first substrate SUB1 that is on the side of the liquid crystal LC, the polymer layer (heat-resistant polymer layer) PI described in Example 1 is provided with the adhesive layer ADL interposed therebetween. On top of the polymer layer PI, the barrier layer BUL (IO1) which is a first inorganic film, the gate insulating layer GI (IO2) which is a second inorganic film, the protecting layer PAS, the pixel electrode PX, and a first alignment layer ORI1 are stacked in order. The pixel electrode PX in the third embodiment, too, can be made from a transparent conductive film such as an indium tin oxide (ITO) film. The pixel electrode PX generates an electric field together with the counter electrode CT, which is provided on the second substrate SUB2 described later in detail, thereby causing molecules of the liquid crystal LC to behave. The pixel electrode PX of the third embodiment therefore has a planar shape. The first alignment layer ORI1, together with a second alignment layer ORI2 described later, determines the initial alignment direction of the molecules of the liquid crystal LC. The first polarizing layer POL1 is disposed on the side of the first substrate SUB1 that is opposite from the liquid crystal LC. The first polarizing layer POL1, together with the second polarizing layer POL2 described later, visualizes the behavior of the molecules of the liquid crystal LC.

The second transparent substrate SUBCF opposed to the first transparent substrate SUBT across the liquid crystal LC includes the second substrate SUB2, which is a polymer member such as a plastic film. On a face of the second substrate SUB2 that is on the side of the liquid crystal LC, the color filter CF, the counter electrode CT, and the second alignment layer ORI2 are stacked in order. The counter electrode CT can be made from a transparent conductive film such as an indium tin oxide (ITO) film. The second polarizing layer POL2 is disposed on the side of the second substrate SUB2 that is opposite from the liquid crystal LC.

### 4.2. Manufacturing Method

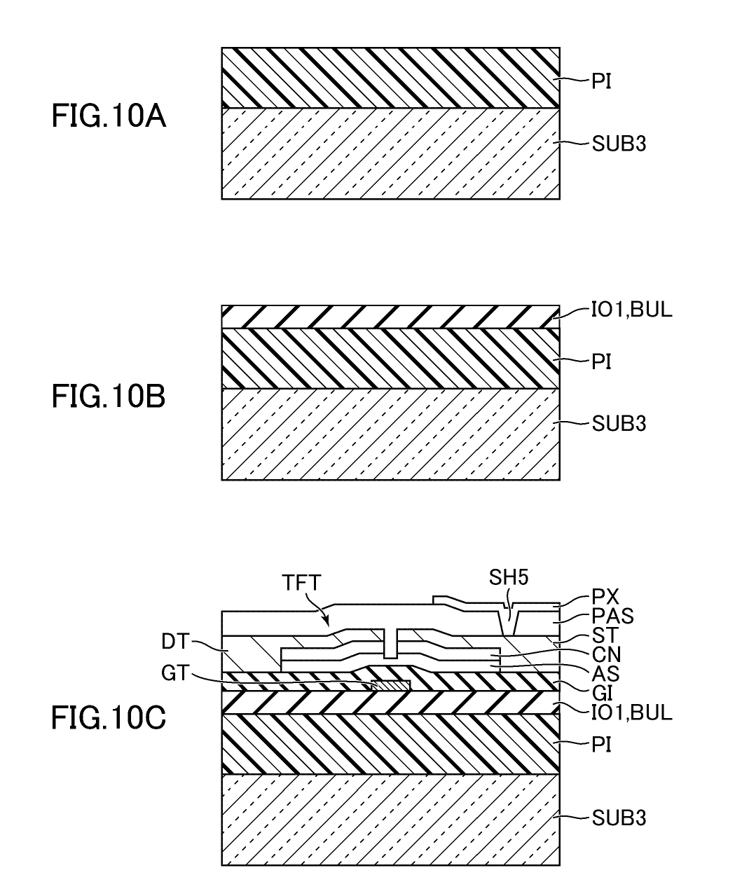

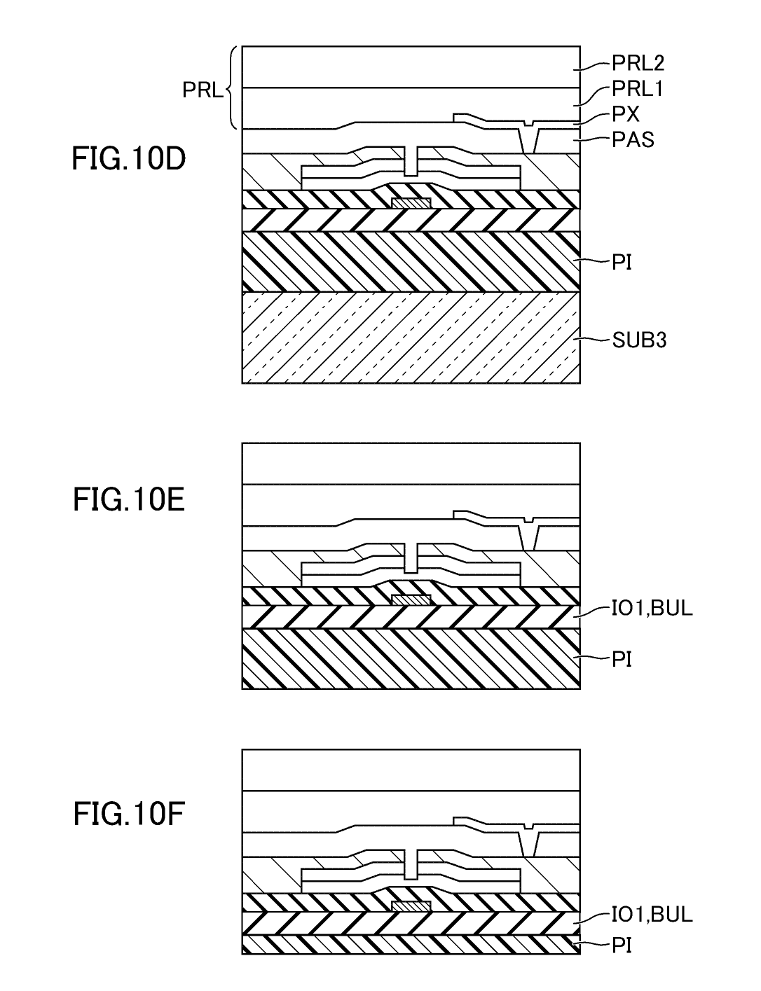

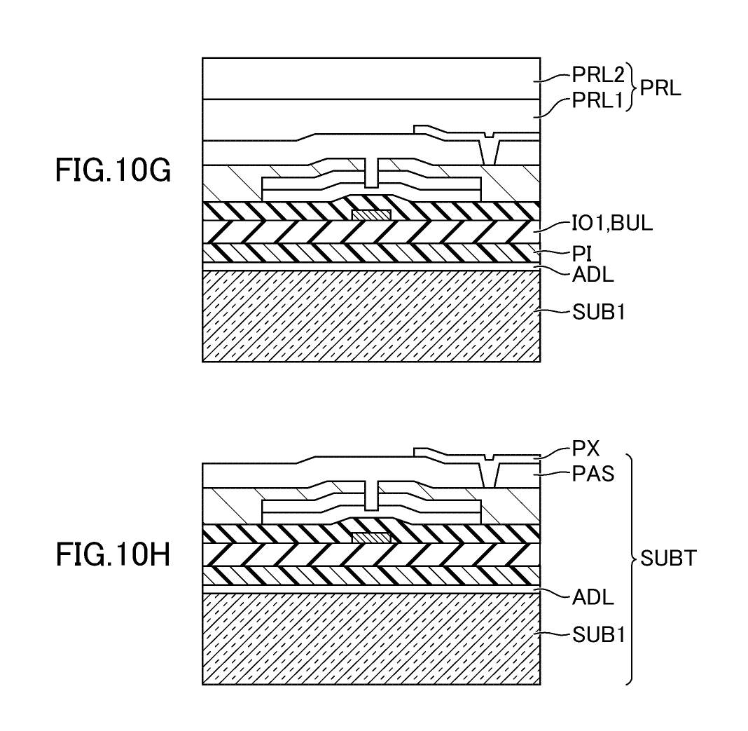

FIGS. 10A, 10B, 10C, 10D, 10E, 10F, 10G, and 10H are diagrams illustrating a method of manufacturing the first transparent substrate in the display device that is a liquid crystal display device according to the third embodiment of the present invention. A method of manufacturing a TN liquid crystal display device that is the liquid crystal display device of the third embodiment is described below with reference to FIGS. 10A to 10H. Note that, the liquid crystal display device of the third embodiment is structured the same way as in the first embodiment except for the thin film transistor TFT and the pixel electrode PX provided thereon. Therefore, the following is mainly a detailed description on the thin film transistor TFT and the pixel electrode PX provided thereon which are structured differently from the first embodiment.

### 4.2.1. Step 3-1 (FIG. 10A)

In the third embodiment, too, a transparent glass substrate is used as the third substrate SUB3, which is a support substrate, in view of the fact that a transparent glass substrate allows laser light irradiation from the rear side and can be recycled. Because the third substrate SUB3 can be recycled and repeatedly used, the manufacture cost of the device, i.e., the liquid crystal display device, is lowered. As in the first embodiment, other substrates than a glass substrate, such as a quartz substrate, a silicon substrate, and a metal substrate, may be used as the third substrate SUB3.

First, the polymer layer (heat-resistant polymer layer) PI is formed to a thickness of 10 μm on the principal surface side (top face in the drawing) of the third substrate SUB3 from a coat of the heat-resistant polymer described in Example 1. The curing conditions, the thickness of the layer, and other conditions in this step are the same as those represented in Example 1.

### 4.2.2. Step 3-2 (FIG. 10B)

Next, as in Step 1-2 described above, the barrier layer BUL is formed on the polymer layer PI. As the barrier layer BUL, an SiON film which is an inorganic film is formed to a thickness of 100 nm at room temperature with an ICP-CVD system.

### 4.2.3. Step 3-3 (FIG. 10C)

Next, the circuit layer containing the thin film transistor TFT, the pixel electrode PX, and other components is formed on the barrier layer BUL by a known deposition method. In the third embodiment, there are formed: the gate electrode GT; the gate insulating layer GI; the semiconductor layer AS; the contact layer CN; the layer forming the drain line DL, which doubles as the drain electrode DT, and the source electrode ST; and the interlayer insulating layer PAS in order on the barrier layer BUL. The through hole SH5 is formed in the interlayer insulating layer PAS to expose the top face of the source electrode ST. The pixel electrode PX having a planar shape is next formed from a transparent conductive material on the interlayer insulating layer PAS. The source electrode ST and the pixel electrode PX are electrically connected to each other via the through hole SH5, thereby completing the circuit layer.

### 4.2.4. Step 3-4 (FIG. 10D)

Next, as in Step 1-4 described above, the protecting layer PRL constituted of the adhesive layer PRL1 and the holding layer PRL2 is adhered temporarily to the top face of the circuit layer supported by the third substrate SUB3. As in Example 1, the protecting layer PRL in the third embodiment is a protecting film that is used in the back grinding of a semiconductor, such as “Icros Tape” (product name) by MITSUI CHEMICALS, INC. or “Revalpha” (product name) by NITTO DENKO CORPORATION.

### 4.2.5. Step 3-5 (FIG. 10E)

Next, as in Step 1-5 described above, the polymer layer PI is irradiated with Xe—Cl excimer laser light having a wavelength of 308 nm from the rear side of the third substrate SUB3, namely, the side where the circuit layer is not provided. The light having a wavelength of 308 nm is absorbed efficiently in the polymer layer PI, and accordingly, the absorption lessens the tight adhesion at the interface between the third substrate SUB3 and the heat-resistant transparent polymer layer PI, with the result that the third substrate SUB3 is separated. The tight adhesion is lessened by fifty shots of exposure at an irradiation dose of 150 mJ/cm²/pulse. In the third embodiment, the circuit layer is sandwiched between the heat-resistant polymer layer PI, which has a thickness of 10 μm, and the protecting layer PRL as in the first embodiment. The third substrate SUB3 serving as a support substrate can therefore be separated without breaking the circuit layer which contains the thin film transistor TFT made of an inorganic material.

### 4.2.6. Step 3-6 (FIG. 10F)

Next, as in Step 1-6 described above, the bottom side of the heat-resistant polymer layer PI in the drawing is asked to reduce the thickness of the heat-resistant polymer layer PI from the initial thickness, 10 μm, which is the thickness of the polymer layer PI at the time of formation, to 1 μm. This increases the transmittance of the polymer layer PI as in the first embodiment, and accordingly improves the luminance of the liquid crystal display device.

### 4.2.7. Step 3-7 (FIG. 10G)

Next, as in Step 1-7 described above, the transparent adhesive ADL is used to adhere the first substrate SUB1 which is a plastic film to the side where the third substrate SUB3 has been adhered (namely, the asked side of the polymer layer PI). The first substrate SUB1 which is a plastic film is thus prepared as a substrate.

### 4.2.8. Step 3-8 (FIG. 10H)

As in Step 1-8 described above, the protecting layer PRL which has been adhered temporarily is separated next. In the third embodiment, too, “Icros Tape” (product name) or “Revalpha” (product name) described above is used as the protecting layer PRL, and hence the adhesion amount of the adhesive layer PRL1 is easily reduced by heating, and the holding layer PRL2 is readily separated along with the adhesive layer PRL1. As a result, the first transparent substrate SUBT is completed in which the thin film transistor TFT is transferred to the plastic film serving as the first substrate SUB1 without being turned upside down and the circuit layer is provided on the first substrate SUB1.

After Step 3-8, a sealing material is used to fix the first transparent substrate SUBT to the second transparent substrate SUBCF, where the color filter CF, the counter electrode CT, and the black matrix layer BM are provided on (the liquid crystal side of) the second substrate SUB2 formed by a known method. Liquid crystal LC is injected between the second transparent substrate SUBCF and the first transparent substrate SUBT, thereby completing the liquid crystal display panel as shown in FIG. 9. A backlight unit and the like are attached to this liquid crystal display panel to obtain a liquid crystal display device. However, because the liquid crystal display device of the third embodiment is a TN liquid crystal display device, the counter electrode CT which is an electrode made of ITO is provided on the side of the second transparent substrate SUBCF as well. Specifically, the second transparent substrate SUBCF uses, for example, a plastic substrate having a thickness of 100 μm as the second substrate SUB2. Barrier layers each having a thickness of 100 nm are formed from SiON on the principal surface side of the second substrate SUB2 and the side of the second substrate SUB2 that is opposite (the rear side, the viewer side) from the principal surface side. This is used as a substrate member. The black matrix layer BM, RGB layers of the color filter CF, and the counter electrode CT are then formed on the principal surface side of the second substrate SUB2. The second substrate SUB2 includes an alignment layer as the topmost layer on its liquid crystal side.

As has been described, in the method of manufacturing the first transparent substrate SUBT in the liquid crystal display device of the third embodiment, the polymer layer PI which is made of the polymer material described in Example 1 and functions as a separating layer is formed on the third substrate SUB3 serving as a support substrate. Thereafter, the circuit layer and others are formed above the polymer layer PI with the barrier layer BUL interposed therebetween. After the protecting layer PRL is adhered temporarily on the circuit layer, the polymer layer PI is irradiated with laser light having a wavelength of 200 nm or more and 400 nm or less from the side of the third substrate SUB3. The laser light is absorbed in the polymer layer PI to separate the third substrate SUB3 from the polymer layer PI on which the circuit layer is provided. After the third substrate SUB3 is separated, the polymer layer PI is thinned, the first substrate SUB1 is adhered to the polymer layer PI, and then the protecting layer PRL which has been adhered temporarily is separated. After the protecting layer PRL is separated, the alignment layer is formed by deposition to complete the first transparent substrate SUBT. Liquid crystal is injected between the first transparent substrate SUBT and the second transparent substrate SUBCF, and the substrates are fixed to each other to obtain a liquid crystal display panel, as shown in FIG. 9. The third embodiment, too, chooses as the polymer layer PI the polybenzoxazole (PBO) described in Example 1 out of polybenzoxazole (PBO), polyamide-imide (PAI), polyimide (PI), and polyamide (PA), which can be used in combination with a cross-linker agent in order to improve the glass transition temperature. The polymer layer PI is formed on the third substrate SUB3 to a thickness of 3 μm or more and 30 μm or less. The same effects as those in the liquid crystal display device manufacturing method of the first embodiment are thus obtained.

### 5. Fourth Embodiment

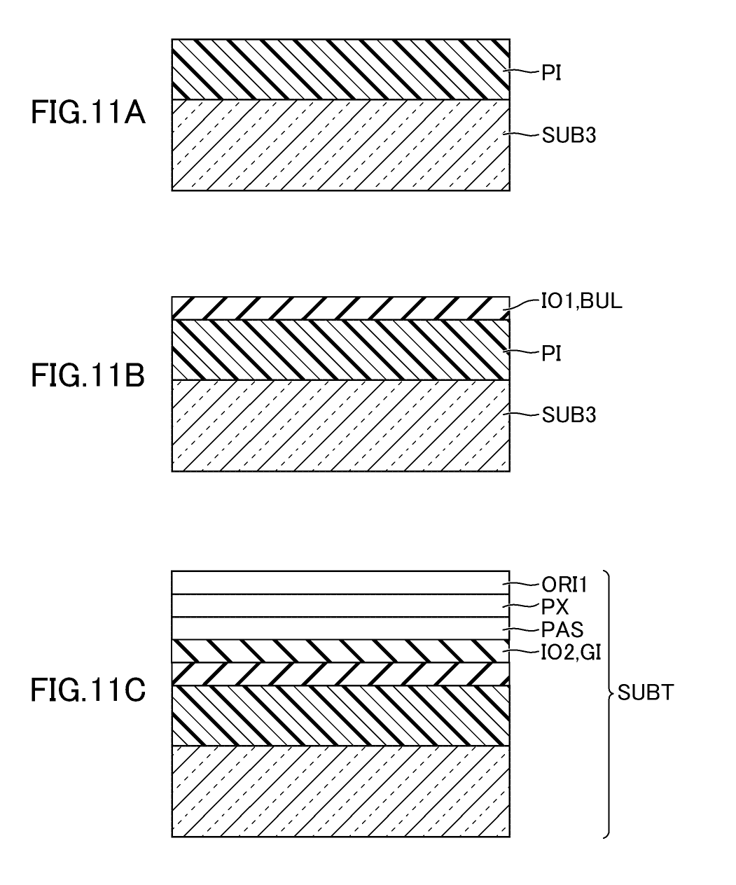

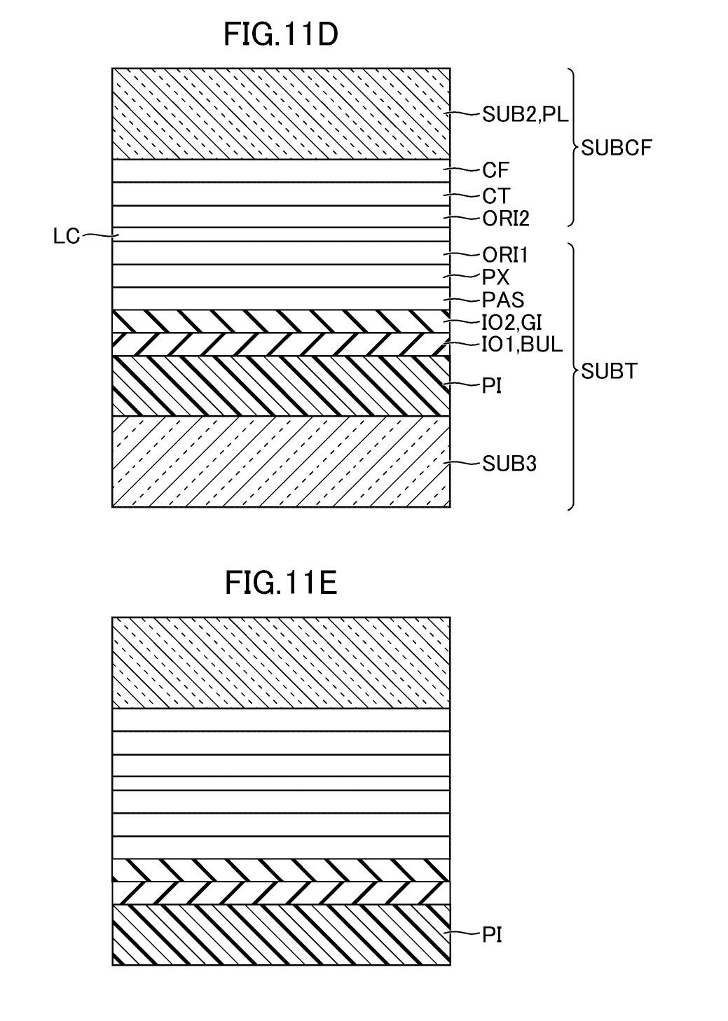

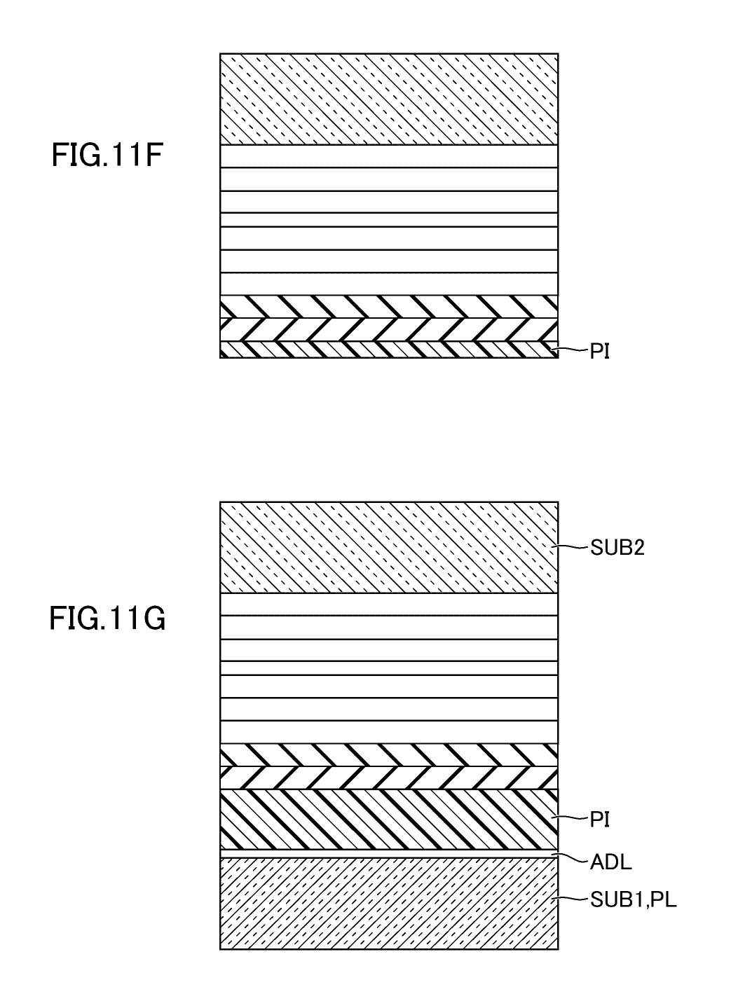

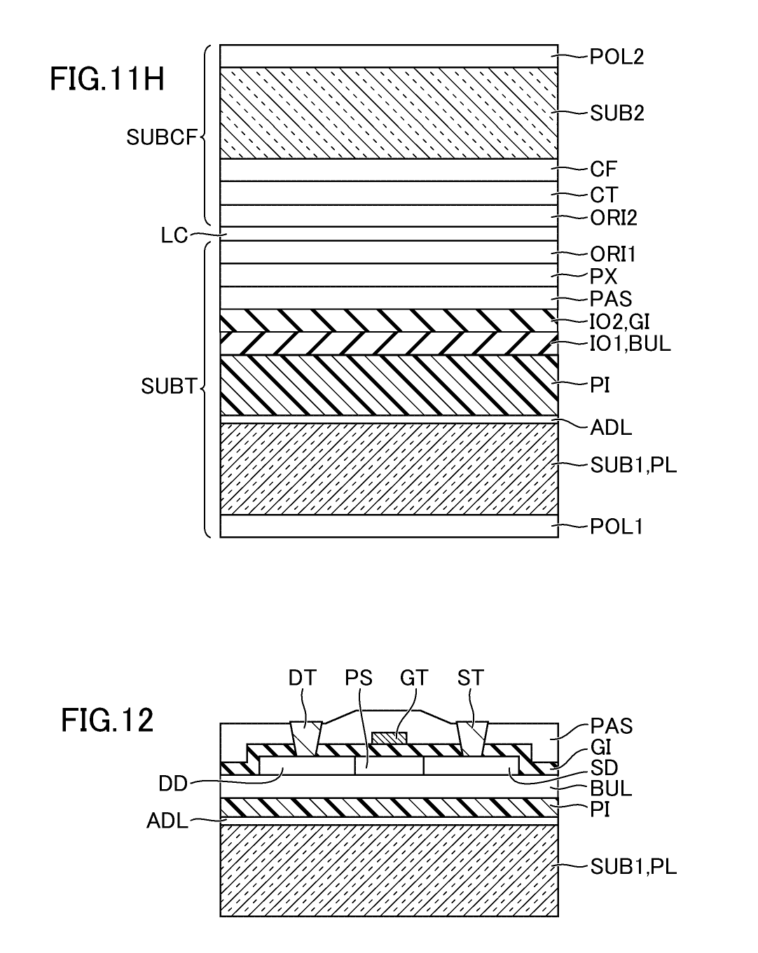

A display device (liquid crystal display device) of the fourth embodiment has the same structure as that of the liquid crystal display device of the third embodiment, but the structure is manufactured by a different method. The method of manufacturing the liquid crystal display device of the fourth embodiment is described below with reference to FIGS. 11A, 11B, 11C, 11D, 11E, 11F, 11G, and 11H. FIGS. 11A to 11H are diagrams illustrating the method of manufacturing a display device that is a liquid crystal display device according to the fourth embodiment of the present invention. Note that, in the manufacturing method of for the liquid crystal display device of the fourth embodiment, the structure is the same as in the liquid crystal display device of third embodiment except that the second transparent substrate SUBCF is used as a supporting member when the third substrate SUB3 is separated. Therefore, the following detailed description focuses on the forming of the polymer layer PI and the second transparent substrate SUBCF.

### 5.1. Manufacturing Method

### 5.1.1. Step 4-1 (FIG. 11A)

As in Step 3-1 described above, a transparent glass substrate is used as the third substrate SUB3. The third substrate SUB3 can thus be recycled and repeatedly used, and the manufacture cost of the device, i.e., the liquid crystal display device, is accordingly lowered. As in the first embodiment, other substrates than a glass substrate, such as a quartz substrate, a silicon substrate, and a metal substrate, may be used as the third substrate SUB3.

First, the polymer layer (heat-resistant polymer layer) PI is formed to a thickness of 10 μm on the principal surface side (top face in the drawing) of the third substrate SUB3 from a coat of the heat-resistant polymer described in Example 1. The curing conditions, the thickness of the layer, and other conditions in this step are the same as those represented in Example 1.

### 5.1.2. Step 4-2 (FIG. 11B)

As in Step 3-2 described above, an SiON film is formed as the barrier layer BUL on the polymer layer PI to a thickness of 100 nm.

### 5.1.3. Step 4-3 (FIG. 11C)

As in Step 3-3 described above, the circuit layer containing the thin film transistor TFT, the pixel electrode PX, and other necessary components of a pixel is formed on the barrier layer BUL by a known deposition method. As is clear from FIG. 11C, in the pixel region, the gate insulating layer GI, the interlayer insulating layer PAS, the pixel electrode PX, and the alignment layer ORI1 are stacked in order on the barrier layer BUL. The circuit layer is formed through this step on the polymer layer PI, which is formed on the third substrate SUB3. A rubbing process suited to the alignment layer ORI1 is performed.

### 5.1.4. Step 4-4 (FIG. 11D)

Next, for example, on the principal surface side of the second substrate SUB2, which is a plastic substrate having a thickness of 100 μm, the not-shown black matrix layer BM, RGB thin-film layers of the color filter CF, the counter electrode CT, and the alignment layer ORI2 are stacked by a known method in order, to thereby complete the second transparent substrate SUBCF.

Next, the second transparent substrate SUBCF and the third substrate SUB3 which has the circuit layer formed in Step 4-3 are fixed to each other with a sealing material, with the alignment layer ORI2 of the second transparent substrate SUBCF and the alignment layer ORI1 of the third substrate SUB3 opposed to each other. When fixing the substrates, liquid crystal LC is injected between the second transparent substrate SUBCF and the third substrate SUB3, and beads spacers are placed in the liquid crystal layer LC.

### 5.1.5. Step 4-5 (FIG. 11E)

As in Step 3-5, the polymer layer PI is irradiated with Xe—Cl excimer laser light having a wavelength of 308 nm from the rear side of the third substrate SUB3, which is a glass substrate, namely, the side where the circuit layer is not provided. As a result, the polymer layer PI efficiently absorbs the light having a wavelength of 308 nm. The absorption lessens the tight adhesion at the interface between the third substrate SUB3 and the heat-resistant transparent polymer layer PI, with the result that the third substrate SUB3 is separated. Also in this case, the tight adhesion is lessened by fifty shots of exposure at an irradiation dose of 150 mJ/cm²/pulse. In the fourth embodiment, as in the second embodiment, the circuit layer is protected by being sandwiched between the second transparent substrate SUBCF and the polymer layer PI. The third substrate SUB3 serving as a support substrate can therefore be separated without breaking the circuit layer which contains the thin film transistor TFT made of an inorganic material.

### 5.1.6. Step 4-6 (FIG. 11F)

Next, as in Step 3-6, the heat-resistant polymer layer PI is asked to reduce the thickness of the heat-resistant polymer layer PI from the initial thickness, 10 μm, to 1 μm. This increases the transmittance of the polymer layer PI as in the first embodiment, and accordingly improves the luminance of the liquid crystal display device.

### 5.1.7. Step 4-7 (FIG. 11G)

As in Step 3-7, the transparent adhesive ADL is used to adhere another substrate, namely, the first substrate SUB1 which is a plastic film, to the surface of the polymer layer PI on the side from which the third substrate SUB3 has been separated (namely, the rear side of the polymer layer PI). The first substrate SUB1 which is a plastic film is thus adhered to the polymer layer PI.

### 5.1.8. Step 4-8 (FIG. 11H)

The polarizing layers POL1 and POL2 are then adhered to the top and the bottom to obtain a liquid crystal display panel that includes, as the first transparent substrate SUBT, the first substrate SUB1 which is a plastic film.

Thereafter, a not-shown backlight unit is disposed on the rear side of the liquid crystal display panel to obtain the liquid crystal display device of the fourth embodiment.

### 5.2. Characteristics

As has been described, in the method of manufacturing the first transparent substrate SUBT of the liquid crystal display device of the fourth embodiment, the polymer layer PI which is made of the polymer material described in Example 1 and functions as a separating layer is formed on the third substrate SUB3 serving as a support substrate. Thereafter, the circuit layer, the alignment layer, and others are formed above the polymer layer PI with the barrier layer BUL interposed therebetween. Liquid crystal LC is then injected between the third substrate SUB3 and the second transparent substrate SUBCF. The substrates are fixed to each other, thereby protecting the circuit layer which contains the thin film transistor TFT with the polymer layer PI and the second transparent substrate SUBCF. Thereafter, the polymer layer PI is irradiated with laser light having a wavelength of 200 nm or more and 400 nm or less from the side of the third substrate SUB3. The laser light is absorbed in the polymer layer PI to separate the third substrate SUB3 at the interface between the polymer layer PI and the third substrate SUB3. After the third substrate SUB3 is separated, the polymer layer PI is thinned and the first substrate SUB1 is adhered to the polymer layer PI, to thereby complete the liquid crystal display panel. The same effects as those in the liquid crystal display device manufacturing method of the first embodiment are thus obtained. In the fourth embodiment, the circuit layer is protected by the second transparent substrate SUBCF and the polymer layer PI against damage from stress when the third substrate SUB3 is separated from the polymer layer PI. The fourth embodiment therefore has a special effect in that, similarly to the display device manufacturing method of the second embodiment, the display device manufacturing method of the fourth embodiment is smaller in number of steps than the display device manufacturing methods of the first and third embodiments.

### 6. Fifth Embodiment

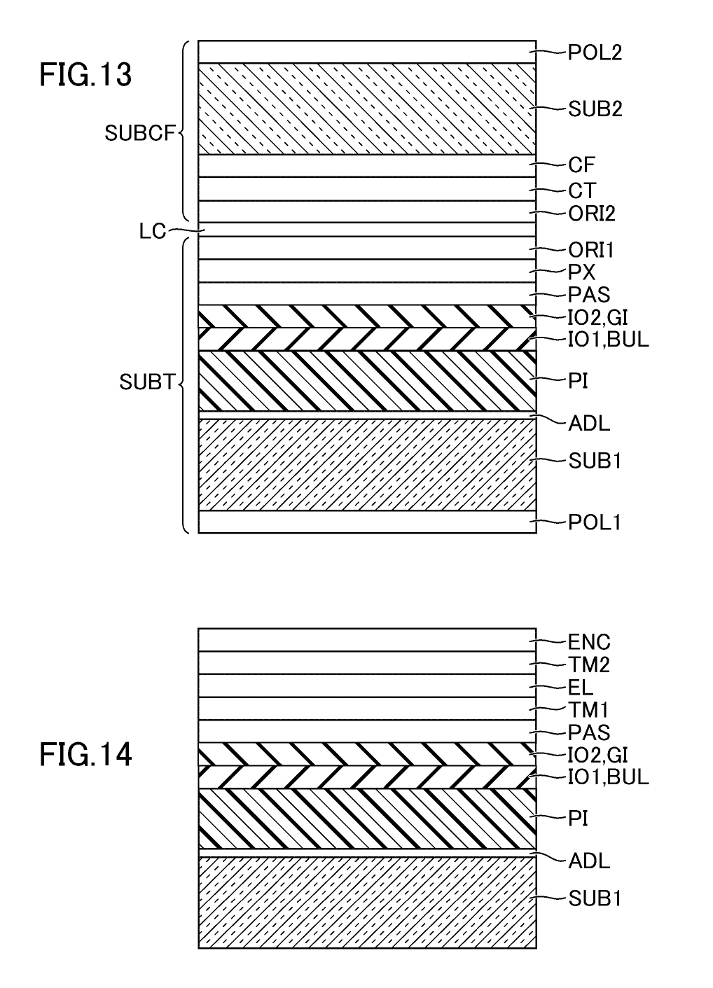

FIG. 12 is a diagram illustrating the schematic structure of a display device that is a liquid crystal display device according to the fifth embodiment of the present invention, in the form of a sectional view of a region where a thin film transistor is formed. FIG. 13 is a diagram illustrating the schematic structure of the display device that is a liquid crystal display device according to the fifth embodiment of the present invention, in the form of a sectional view of a region where a pixel is formed. The sectional view of FIG. 13 in particular illustrates the first transparent substrate side. The liquid crystal display device of the fifth embodiment is structured the same way as a conventional liquid crystal display device, except for the structure of the polymer layer PI which has heat resistance (heat-resistant polymer layer). The following description therefore focuses on details of the structure of the polymer layer. The pixel electrode and other components that are provided above the thin film transistor are omitted from the sectional view of FIG. 12.

### 6.1. Structure

In the display device of the fifth embodiment, a semiconductor layer PS of the thin film transistor is made of polysilicon (including low temperature polysilicon and microcrystalline polysilicon). A TFT structure suitable for the thin film transistor TFT that uses polysilicon for the semiconductor layer PS is, as is obvious from FIG. 12, the top gate structure in which the gate electrode GT is provided on a polysilicon layer serving as the semiconductor layer PS. This thin film transistor TFT has a known structure in which a source region SD and a drain region DD are provided by the sides of the semiconductor layer PS, namely, the sides of a channel layer.

As illustrated in FIG. 12, the polymer layer PI which is a heat-resistant polymer layer asked to a thickness of 1 μm is first provided on the first transparent substrate of the fifth embodiment. The barrier layer BUL which is, for example, a silicon nitride (SiN) film is provided on the front face of the polymer layer PI. The barrier layer BUL is provided in order to avoid the infiltration of metal atoms within the polymer layer PI into the semiconductor layer PS. The rear side (the side opposite from the side where the thin film transistor TFT is provided) of the polymer layer PI, on the other hand, is adhered via the adhesive layer ADL to the first substrate SUB1, which is a polymer substrate.

The semiconductor layer PS made of polysilicon is provided on the front face of the barrier layer BUL, namely, the top face of the barrier layer BUL in the drawing, and the gate insulating layer GI is provided to cover the underlying surface including the semiconductor layer PS. The gate electrode GT is provided on the gate insulating layer GI so as to stretch across the semiconductor layer PS. After the gate electrode GT is formed, the semiconductor layer PS is doped with impurities, with the gate electrode GT as a mask, to thereby form the drain region DD and the source region SD. The protecting layer PAS is provided on the gate insulating layer GI to cover the underlying surface including the gate electrode GT. Openings (through holes) are provided in the protecting layer PAS and the gate insulating layer GI. The drain electrode DT and the source electrode ST are provided to be connected via the openings to the drain region DD and to the source region SD, respectively. The thin film transistor TFT of the fifth embodiment is thus structured.

As illustrated in FIG. 13, a pixel region in the liquid crystal display device of the fifth embodiment has the same structure as that of the pixel regions in the liquid crystal display devices of the third and fourth embodiments. Specifically, the first transparent substrate SUBT including the first substrate SUB1, which is made of a polymer, and the second transparent substrate SUBCF including the second substrate SUB2, which is made of a polymer, are opposed to each other across the liquid crystal layer LC. The polymer layer (heat-resistant polymer layer) PI is adhered via the adhesive layer ADL to the principal surface (opposed face) of the first substrate SUB1, namely, a face of the first substrate SUB1 that is on the side of the liquid crystal layer LC. On top of the polymer layer PI, the barrier layer BUL (IO1) which is the first inorganic film, the gate insulating layer GI (IO2) which is the second inorganic film, the protecting layer PAS, the pixel electrode PX, and the first alignment layer ORI1 are stacked in order. On a face of the second substrate SUB2 that is on the side of the liquid crystal LC, the color filter CF, the counter electrode CT, and the second alignment layer ORI2 are stacked in order. The counter electrode CT can be made from a transparent conductive film such as an indium tin oxide (ITO) film. The first polarizing POL1 and the second polarizinge POL2 are disposed on the sides of the first substrate SUB1 and the second substrate SUB2 that are opposite from the liquid crystal LC.

### 6.2. Manufacturing Method and Characteristics

The liquid crystal display device of the fifth embodiment is manufactured by the same steps as those of the liquid crystal display device manufacturing methods of the third and fourth embodiments, except for the step of forming the circuit layer. Therefore, the liquid crystal display device of the fifth embodiment provides the same effects as those obtained with the liquid crystal display devices of the third and fourth embodiments.

### 7. Sixth Embodiment

FIG. 14 is a sectional view illustrating the schematic structure of a display device that is an organic electroluminescent display device according to a sixth embodiment of the present invention. However, the present invention is also applicable to other self-luminous display devices than organic electroluminescent display devices. Similarly to FIG. 9 described above, the sectional view of FIG. 14 illustrates a pixel region.

### 7.1. Structure

As illustrated in FIG. 14, the organic electroluminescent display device of the sixth embodiment is provided with the heat-resistant polymer layer PI, in particular, the polymer layer PI having a thickness of about 1 μm as in the display devices of the first to fifth embodiments. In the organic electroluminescent display device of the sixth embodiment, the polymer layer PI is a heat-resistant polymer layer asked to a thickness of 1 μm. The barrier layer BUL which is, for example, a silicon nitride (SiN) film is provided on the front face of the polymer layer PI. The barrier layer BUL is provided in order to avoid the infiltration of metal atoms within the polymer layer PI into the semiconductor layer PS. The rear side (the side opposite from the side where the thin film transistor TFT is provided) of the polymer layer PI, on the other hand, is adhered via the adhesive layer ADL to the first substrate SUB1, which is a polymer substrate.

On top of the polymer layer PI, the barrier layer BUL (IO1) which is the first inorganic film, the gate insulating layer GI (IO2) which is the second inorganic film, the protecting layer PAS, a first electrode TM1, an emitting layer EL, a second electrode TM2, and a sealing layer ENC are stacked in order. In the organic electroluminescent display device of the sixth embodiment, the barrier layer BUL functions as a stress adjusting film, and the gate insulating layer GI in a not-shown region where the thin film transistor is formed functions as a gate insulating layer provided between a semiconductor layer and a gate electrode. The emitting layer EL is sandwiched between the first electrode TM1 and the second electrode TM2 to emit light in a manner determined by a current that flows in the emitting layer EL through the first electrode TM1 and the second electrode TM2. In the organic electroluminescent display device of the sixth embodiment, a transparent conductive film such as an ITO film can be used for the electrode that is closer to the first substrate SUB1 than the emitting layer EL is, and light emitted from the emitting layer EL is cast to the outside through the first electrode TM1 formed from a transparent conductive film. The second electrode TM2 may be formed from a transparent conductive film as well.

### 7.2. Manufacturing Method

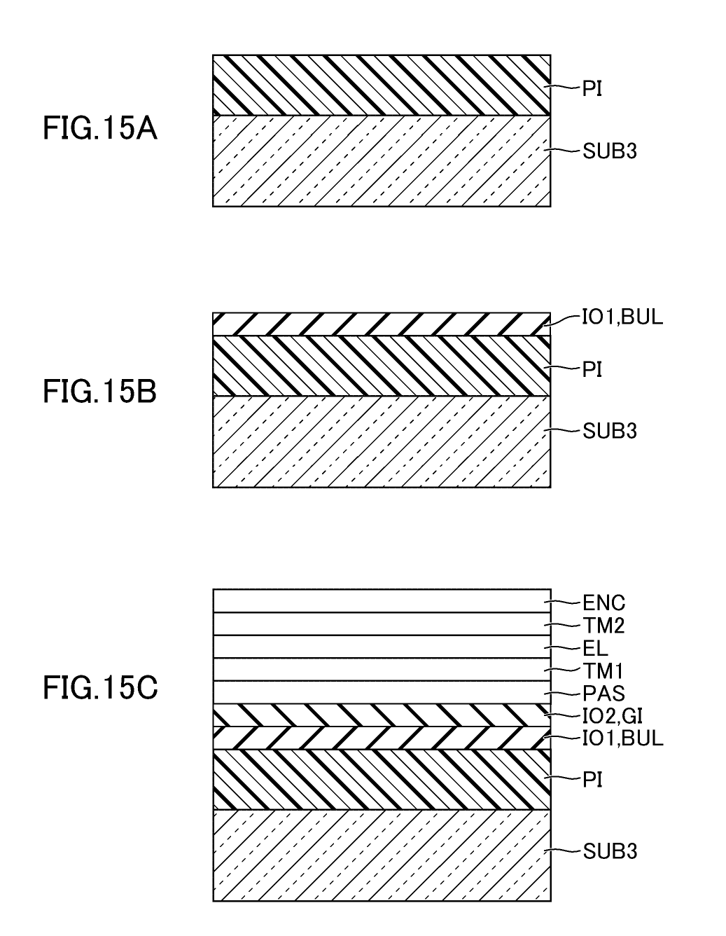

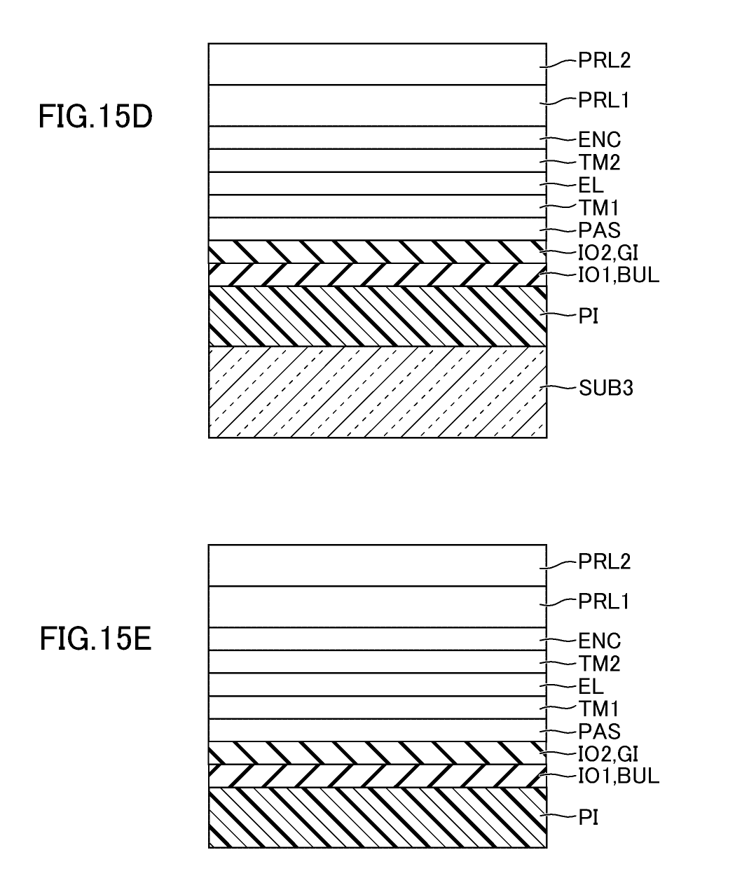

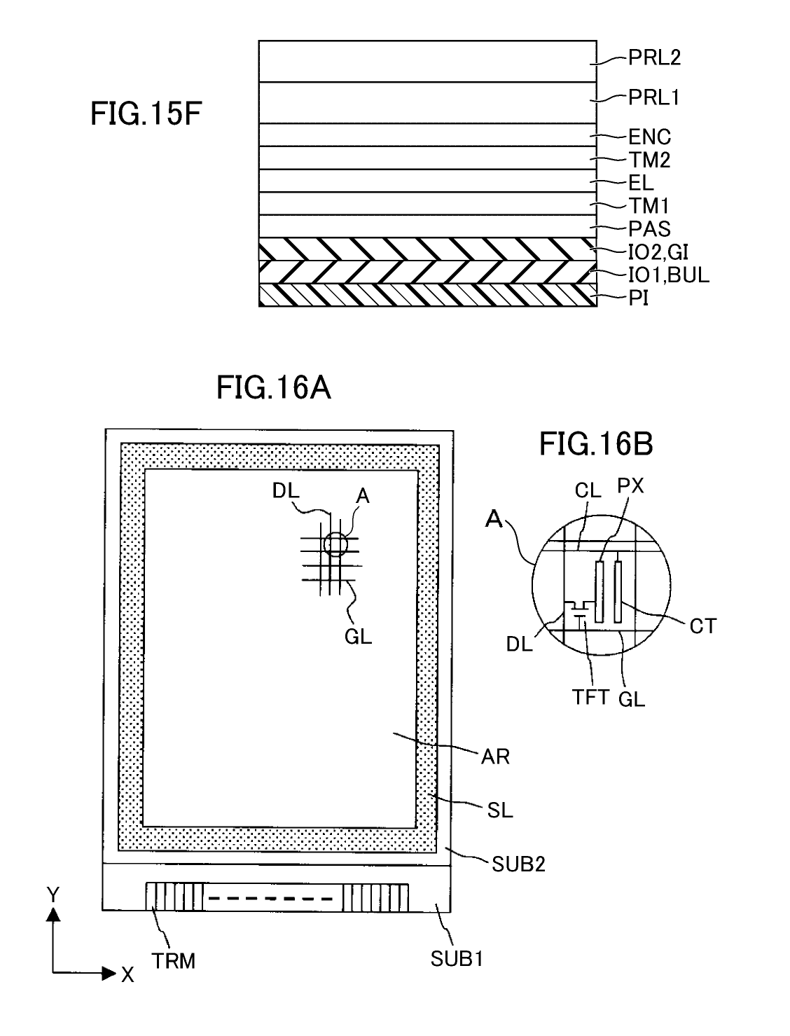

FIGS. 15A, 15B, 15C, 15D, 15E, and 15F are diagrams illustrating a method of manufacturing the display device that is a organic electroluminescent display device according to the sixth embodiment of the present invention. The method of manufacturing the organic electroluminescent display device of the sixth embodiment is described below with reference to FIGS. 15A to 15F. The following description deals with a bottom emission method in which a transparent conductive film is used to form the first electrode TM1 provided at a shorter distance to the first substrate SUB1 than the distance between the emitting layer EL and the first substrate SUB1, and light from the emitting layer EL is cast through the first electrode TM1 and the first substrate SUB1. However, the present invention is also applicable to a top emission method in which the second electrode TM2 is formed from a transparent conductive film and light from the emitting layer EL is cast through the second electrode TM2 and the sealing layer ENC.

### 7.2.1. Step 6-1 (FIG. 15A)

In the sixth embodiment, too, a transparent glass substrate is used as the third substrate SUB3 in view of the fact that a transparent glass substrate allows laser light irradiation from the rear side and can be recycled. The third substrate SUB3 can thus be recycled and repeatedly used, and the manufacture cost of the device, i.e., the organic electroluminescent display device, is accordingly lowered. However, a substrate chosen as the third substrate SUB3 needs to be made of a material suitable for the high temperature in evaporation executed to form the emitting layer EL which is described later. As in the first embodiment, other substrates than a glass substrate, such as a quartz substrate, a silicon substrate, and a metal substrate, may be used as the third substrate SUB3. The third substrate SUB3 is desirably a transparent substrate such as a glass substrate or a quartz substrate because a transparent substrate allows laser light irradiation from the rear side as described later.

First, the polymer layer (heat-resistant polymer layer) PI is formed to a thickness of 10 μm on the principal surface side (top face in the drawing) of the third substrate SUB3 from a coat of the heat-resistant polymer described in Example 1. Suitable curing conditions, layer thickness, and the like can be selected for this step.

### 7.2.2. Step 6-2 (FIG. 15B)

Next, the barrier layer BUL is formed on the polymer layer PI. As the barrier layer BUL, an SiON film, which is an inorganic film, is formed to a thickness of 100 nm at room temperature with an ICP-CVD system.

### 7.2.3. Step 6-3 (FIG. 15C)

Next, a driver thin film transistor, which adjusts the amount of current supplied to the emitting layer EL, a switching thin film transistor, which controls the fetching of a video signal and also controls the driving of the driver thin film transistor, wiring, and other components are formed on the barrier layer BUL by a known deposition method. Formed next are the first electrode TM1, which is formed from a transparent conductive film such as an ITO film, the emitting layer EM, which is an organic thin film, the second electrode TM2, and the sealing layer ENC.

In other words, the switching thin film transistor, the driver thin film transistor, the wiring, and other components are formed by sequentially forming on the barrier layer BUL: a layer for forming the gate line and the gate electrode; the gate insulating layer GI; the semiconductor layer; a layer for forming the drain line, which doubles as the drain electrode, and the source electrode; and the interlayer insulating layer PAS. Next, a through hole (not shown) that exposes the top face of the source electrode of the driver thin film transistor is formed in the interlayer insulating layer PAS, and the first electrode TM1 is then formed on the interlayer insulating layer PAS from a transparent electrode material, thereby electrically connecting the source electrode and the first electrode TM1. The emitting layer EM is formed on the first electrode TM1 from a thin-film layer of an organic material with the use of a shadow mask. The second electrode TM2 is formed on the emitting layer EL from a metal thin film. Thereafter, the sealing layer ENC is formed on the second electrode TM2 so as to cover the principal surface side of the substrate, thereby preventing moisture and the like from infiltrating into the organic material that constitutes the emitting layer EL. The second electrode TM2 is electrically connected to a not-shown common signal line, which is formed in Step 6-3, by, for example, forming the second electrode TM2 after a through hole is formed in the interlayer insulating layer PAS, which is provided on the common signal line.

### 7.2.4. Step 6-4 (FIG. 15D)

Next, as in Step 1-4, the protecting layer PRL constituted of the adhesive layer PRL1 and the holding layer PRL2 is adhered temporarily to the top face of the sealing layer ENC. Also in the sixth embodiment, the protecting layer PRL is, for example, as described in Example 1, a protecting film used in the back grinding of a semiconductor, such as “Icros Tape” (product name) by MITSUI CHEMICALS, INC. or “Revalpha” (product name) by NITTO DENKO CORPORATION.

### 7.2.5. Step 6-5 (FIG. 15E)

Next, as in Step 1-5, the polymer layer PI is irradiated with Xe—Cl excimer laser light having a wavelength of 308 nm from the rear side of the third substrate SUB3 which is a glass substrate, namely, the side where the circuit layer is not provided. With this laser light irradiation, the light having a wavelength of 308 nm is absorbed efficiently in the heat-resistant polymer layer PI of the sixth embodiment, too, and accordingly, the absorption lessens the tight adhesion at the interface between the third substrate SUB3 and the heat-resistant transparent polymer layer PI, with the result that the third substrate SUB3 is separated. In the sixth embodiment, too, the circuit layer is sandwiched between the heat-resistant polymer layer PI, which has a thickness of 10 μm, and the protecting layer PRL as in the first embodiment. The third substrate SUB3 serving as a support substrate can therefore be separated without breaking the circuit layer which includes the thin film transistor TFT made of an inorganic material.

### 7.2.6. Step 6-6 (FIG. 15F)

Next, the bottom side of the heat-resistant polymer layer PI in the drawing is asked to reduce the thickness of the heat-resistant polymer layer PI from the initial thickness, 10 μm, to 1 μm. This increases the transmittance of the polymer layer PI as in the first embodiment, and accordingly improves the luminance of the liquid crystal display device.

### 7.2.7. Step 6-7 (FIG. 14)

Next, the transparent adhesive ADL is used to adhere another substrate, namely, the first substrate SUB1 which is a plastic film to the side where the third substrate SUB3 has been adhered. The first substrate SUB1 which is a plastic film is thus adhered to the polymer layer PI.

The protecting layer PRL which has been adhered temporarily is separated next. In the case where “Icros Tape” (product name) or “Revalpha” (product name) is used as the protecting layer PRL, the adhesion amount of the adhesive layer PRL1 is easily reduced by heating, and the holding layer PRL2 is readily separated along with the adhesive layer PRL1. As a result, the organic electroluminescent display device is completed in which the thin film transistor TFT is transferred to the plastic film serving as the first substrate SUB1 without being turned upside down and the circuit layer including the thin film transistor and the emitting layer EL is provided on the first substrate SUB1.

### 7.3. Characteristics

As has been described, in the method of manufacturing the organic electroluminescent display device of the sixth embodiment, too, the polymer layer PI which has heat resistance and high transmittance in the visible light range and which is made of the polymer material described in Example 1 and functions as a separating layer is formed on the third substrate SUB3 serving as a support substrate, and then the circuit layer is formed above the polymer layer PI with the barrier layer BUL interposed therebetween. Next, the protecting layer PRL is temporarily adhered to the top face of the circuit layer, and the polymer layer PI is then irradiated with laser light having a wavelength of 200 nm or more and 400 nm or less from the side of the third substrate SUB3. The laser light is absorbed in the polymer layer PI, to thereby separate the third substrate SUB3 from the polymer layer PI on which the circuit layer is provided. Next, the polymer layer PI is ashed from the separation side, thereby being reduced in thickness from 10 μm, which is the thickness of the polymer layer PI at the time of formation, to 1 μm. After this thinning of the polymer layer PI, the first substrate SUB1 is adhered to the ashed side of the polymer layer PI with a transparent adhesive, and the protecting layer PRL which has been adhered temporarily is subsequently separated, to thereby obtain the organic electroluminescent display device. The sixth embodiment, too, chooses as the polymer layer PI the polybenzoxazole (PBO) described in Example 1 out of polybenzoxazole (PBO), polyamide-imide (PAI), polyimide (PI), and polyamide (PA), which can be used in combination with a cross-linker agent in order to improve the glass transition temperature. The polymer layer PI is formed on the third substrate SUB3 to a thickness of 3 μm or more and 30 μm or less. As a result, when the polymer layer PI on which the circuit layer is provided is separated from the third substrate SUB3, the thin film transistors and other components that constitute the circuit layer are prevented from breaking. In addition, because a glass substrate is used as the third substrate SUB3 and the polymer layer PI is used as a separating layer, the third substrate SUB3 can easily be reused in a conventional manufacture system. Further, in the method of manufacturing the organic electroluminescent display device of the sixth embodiment, where the polymer layer PI of Example 1 formed on the third substrate SUB3 is separated from the third substrate SUB3 and then thinned and adhered to the first substrate SUB1, the transmittance of light from the emitting layer is improved despite the use of the heat-resistant polymer layer PI. The organic electroluminescent display device of the sixth embodiment is consequently improved in luminance.

### 8. Seventh Embodiment

FIG. 16A is a plan view illustrating the schematic structure of a display device, that is a liquid crystal display device according to a seventh embodiment of the present invention. The liquid crystal display device of the seventh embodiment is manufactured by the manufacturing methods of the first to fifth embodiments described above. Symbols X and Y in FIG. 16A represent an X axis and a Y axis, respectively.

### 8.1. Structure

As illustrated in FIG. 16A, the liquid crystal display device of the seventh embodiment includes the first substrate SUB1 and the second substrate SUB2 which are opposed to each other with a liquid crystal (not shown) sandwiched therebetween. The second substrate SUB2 is disposed on the viewer side. A backlight unit (not shown) is disposed at the back of the first substrate SUB1. The second substrate SUB2 is slightly smaller in area than the first substrate SUB1, thereby exposing a terminal portion TRM which is located in a lower part of the first substrate SUB1 in the drawing. A sealing material SL is provided along the perimeter of the second substrate SUB2 to be fixed to the first substrate SUB1. The sealing material SL also has a function of sealing the liquid crystal.

The region enclosed by the sealing material SL is the display region AR. In the display region AR, the gate lines GL, which run in the direction X and are placed side by side in the direction Y in the drawing, and the drain lines DL, which run in the direction Y and are placed side by side in the direction X in the drawing, are provided on the liquid crystal side of the first substrate SUB1. A region enclosed by a pair of adjacent gate lines GL and a pair of adjacent drain lines DL constitute a pixel region. The display region AR thus has a large number of pixels arranged in a matrix pattern.

FIG. 16B is an enlarged view of a circular mark A of FIG. 16A. As illustrated in FIG. 16B, which is an enlarged view of a circular mark A of FIG. 16A, each pixel region is provided with the thin film transistor TFT which is turned on by a signal from the relevant gate line GL (scanning signal), the pixel electrode PX to which a signal from the relevant drain line DL (video signal) is supplied through the thin film transistor TFT, and the counter electrode CT which generates an electric field together with the pixel electrode PX. This electric field has a component parallel to the plane of the first substrate SUB1, and changes the alignment of the liquid crystal molecules while the liquid crystal molecules are kept horizontal with respect to the plane of the first substrate SUB1. This type of liquid crystal display device is called, for example, a lateral field (IPS) liquid crystal display device. A reference signal which serves as the reference for a video signal is supplied to the counter electrode CT via, for example, common lines CL running parallel to the gate lines GL. In twisted nematic (TN) or vertical alignment (VA) liquid crystal display devices which are called vertical field liquid crystal display devices, the counter electrode CT is provided on the side of the second substrate SUB2 as described above.

The gate lines GL, the drain lines DL, and the common lines CL are respectively connected to the terminal portion TRM by not-shown lead-out lines so that scanning signals, video signals, and reference signals are supplied via the terminal portion TRM to the gate lines GL, the drain lines DL, and the common lines CL, respectively.

### 8.2. Manufacturing Method and Characteristics

In the display device manufacturing methods of the first to fifth embodiments, a heat-resistant polymer layer can be employed as the polymer layer formed on the liquid crystal side of the first substrate SUB1. This means that conventional manufacture steps can be used to form the circuit layer provided on the polymer layer, and increases the transmittance of the polymer layer provided on the liquid crystal side of the first substrate SUB1. The liquid crystal display devices are thus improved in luminance.

In the first to sixth embodiments which deal with a method of manufacturing a display device, a case of using a glass substrate as the third substrate SUB3 is described in detail. If a quartz substrate, for example, is used instead as the third substrate SUB3, the temperature can be set high when the polymer layer PI or the circuit layer is formed. Using a quartz substrate as the third substrate SUB3 also allows the use of laser light that has a shorter wavelength, in other words, larger energy, when the third substrate SUB3 is separated. For example, the heat-resistant transparent polymer layer (polymer layer) PI is formed to a thickness of 10 μm on the third substrate SUB3, which is a quartz substrate, by curing the polymer material of Example 1 through baking at 320° C. for sixty minutes in a nitrogen atmosphere. The circuit layer is next formed on this polymer layer PI by the manufacturing methods of the first to sixth embodiments. In the subsequent step of separating the third substrate SUB3, making use of the fact that a quartz substrate transmits ultraviolet light which has a shorter wavelength and is poorly transmitted through glass, the polymer layer PI is irradiated with KrF excimer laser light (50 mJ/cm²/pulse, one pulse equals twenty nanoseconds) having a wavelength of 248 nm from the rear side of the third substrate SUB3, after the protecting layer PRL is adhered. The heat-resistant polymer layer PI of Example 1 efficiently absorbs the light having a wavelength of 248 nm, thereby lessening the tight adhesion at the interface between the quartz substrate and the heat-resistant transparent polymer layer. Accordingly, the substrate becomes ready to separate in five pulses, which correspond to an irradiation dose of 250 mJ/cm².

While there have been described what are at present considered to be certain embodiments of the invention, it will be understood that various modifications may be made thereto, and it is intended that the appended claims cover all such modifications as fall within the true spirit and scope of the invention.

What is claimed is:

1. A method of manufacturing a display device, comprising:
forming a polymer layer which comprises an organic material on a principal surface side of a support substrate;
forming one of a semiconductor circuit and a display circuit on the polymer layer;
irradiating the polymer layer from the support substrate side with light having a wavelength that is absorbed in the polymer layer, to thereby separate the polymer layer from the support substrate;
one of thinning and removing the polymer layer; and
adhering a first substrate to one of a surface of the polymer layer and a face where the polymer layer has been provided.

2. The method of manufacturing a display device according to claim 1, wherein the polymer layer has a glass transition temperature of 250° C. or higher.

3. The method of manufacturing a display device according to claim 1, wherein the polymer layer comprises one selected from polybenzoxazole, polyamide-imide, polyimide, and polyamide.

4. The method of manufacturing a display device according to claim 1, wherein the polymer layer disposed on the support substrate has a thickness of 3 μm or more and 30 μm or less.

5. The method of manufacturing a display device according to claim 1, wherein the light having a wavelength that is absorbed in the polymer layer is light having a wavelength of 200 nm or more and 400 nm or less.

6. The method of manufacturing a display device according to claim 1, wherein the light having a wavelength that is absorbed in the polymer layer is XeCl excimer laser light.

7. The method of manufacturing a display device according to claim 1, wherein the first substrate comprises a bendable transparent substrate.

8. The method of manufacturing a display device according to claim 1, wherein the support substrate comprises one of a glass substrate and a quartz substrate.

9. The method of manufacturing a display device according to claim 1, wherein the one of thinning and removing the polymer layer comprises reducing the polymer layer in thickness to 2 μm or less.

10. The method of manufacturing a display device according to claim 1, wherein the semiconductor circuit comprises an amorphous silicon thin film transistor.

11. The method of manufacturing a display device according to claim 1, wherein the display device is a liquid crystal display device.

12. The method of manufacturing a display device according to claim 1, wherein the display device is an organic electroluminescent display device.
